(19) United States
(12) Patent Application Publication
(10) Pub. No.: US 2024/0244865 A1
(43) Pub. Date: Jul. 18, 2024

(54) ORGANIC LIGHT EMITTING DEVICE COMPRISING ORGANOMETALLIC COMPOUND AND PLURALITY OF HOST MATERIALS

(71) Applicant: LG Display Co., Ltd., Seoul (KR)

(72) Inventors: Kusun CHOUNG, Seoul (KR); Hansol PARK, Goyang-si (KR); Yoojeong JEONG, Seoul (KR)

(73) Assignee: LG Display Co., Ltd., Seoul (KR)

(21) Appl. No.: 18/391,564

(22) Filed: Dec. 20, 2023

(30) Foreign Application Priority Data
Dec. 28, 2022 (KR) 10-2022-0188038

(51) Int. Cl. H10K 50/12; H10K 50/13; H10K 50/15; H10K 50/16; H10K 50/17; H10K 85/30; H10K 85/60

(52) U.S. Cl. CPC H10K 50/12; H10K 50/13; H10K 50/15; H10K 50/16; H10K 50/171; H10K 85/342; H10K 85/6572; H10K 85/6574

(57) ABSTRACT

Disclosed is an organic light-emitting device including: a first electrode; a second electrode facing the first electrode; and an organic layer disposed between the first electrode and the second electrode; wherein the organic layer includes a light-emissive layer, wherein the light-emissive layer includes a dopant material and a host material, wherein the dopant material includes an organometallic compound represented by Chemical Formula 1, wherein the host material includes a mixture of a compound represented by Chemical Formula 2 and a compound represented by Chemical Formula 3. The organic light-emitting device has excellent light-emitting efficiency and lifespan.

### CROSS-REFERENCE TO RELATED APPLICATION

This application claims priority from Korean Patent Application No. 10-2022-0188038 filed on Dec. 28, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to an organic light-emitting device including an organometallic compound and a plurality of host materials.

### Description of Related Art

As a display device is applied to various fields, interest with the display device is increasing. One of the display devices is an organic light-emitting display device including an organic light-emitting diode (OLED) which is rapidly developing.

In the organic light-emitting diode, when electric charges are injected into a light-emitting layer formed between a positive electrode and a negative electrode, an electron and a hole are recombined with each other in the light-emitting layer to form an exciton and thus energy of the exciton is converted to light. Thus, the organic light-emitting diode emits the light. Compared to conventional display devices, the organic light-emitting diode may operate at a low voltage, consume relatively little power, render excellent colors, and may be used in a variety of ways because a flexible substrate may be applied thereto. Further, a size of the organic light-emitting diode may be freely adjustable.

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer and thus excitons are generated in the light-emitting layer and then fall to a ground state to emit light.

Organic materials used in the organic light-emitting diode may be largely classified into light-emitting materials and charge-transporting materials. The light-emitting material is an important factor determining luminous efficiency of the organic light-emitting diode. The luminescent material has high quantum efficiency, excellent electron and hole mobility, and is uniform and stable in the light-emitting layer. The light-emitting materials may be classified into light-emitting materials emitting light of blue, red, and green colors based on colors of the light. A color-generating material may include a host and dopants to increase the color purity and luminous efficiency through energy transfer.

When the fluorescent material is used, singlets as about 25% of excitons generated in the light-emitting layer are used to emit light, while most of triplets as 75% of the excitons generated in the light-emitting layer are dissipated as heat. However, when the phosphorescent material is used, singlets and triplets are used to emit light.

Conventionally, an organometallic compound is used as the phosphorescent material used in the organic light-emitting diode. There is still a technical need to improve performance of an organic light-emitting diode by deriving a high-efficiency phosphorescent dopant materials and applying a host material of optimal photophysical properties to improve diode efficiency and lifetime, compared to a conventional organic light-emitting diode.

### SUMMARY

Accordingly, one of the purposes of the present disclosure is to provide an organic light-emitting diode in which an organic light-emitting layer contains an organometallic compound and a plurality of host materials capable of lowering operation voltage, and improving efficiency, and lifespan.

Purposes of the present disclosure are not limited to the above-mentioned purpose. Other purposes and advantages of the present disclosure that are not mentioned may be understood based on following descriptions, and may be more clearly understood based on embodiments of the present disclosure. Further, it will be easily understood that the purposes and advantages of the present disclosure may be realized using means shown in the claims and combinations thereof.

In order to achieve the above purpose, the present disclosure may provide an organic light-emitting device comprising: a first electrode; a second electrode facing the first electrode; and an organic layer disposed between the first electrode and the second electrode; wherein the organic layer includes a light-emissive layer, wherein the light-emissive layer includes a dopant material and a host material, wherein the dopant material includes an organometallic compound represented by Chemical Formula 1, wherein the host material includes a mixture of a compound represented by Chemical Formula 2 and a compound represented by Chemical Formula 3:

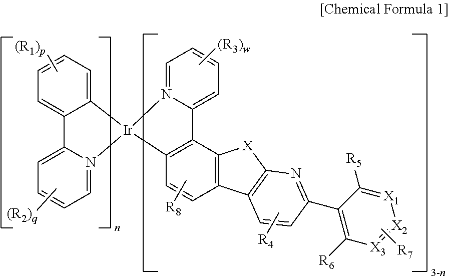

wherein in Chemical Formula 1,
X represents one selected from a group consisting of oxygen (O), sulfur (S) and selenium (Se),
each of X₁, X₂ and X₃ independently represents nitrogen (N) or CR′,
each of R₁, R₂, R₃, R₄, R₇, R₈ and R′ independently represents one selected from a group consisting of hydrogen, deuterium, halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₁, R₂, R₃, R₄, R₇, R₈ and R′ may be substituted with deuterium,
wherein each of R₅ and R₆ independently represents one selected from a group consisting of halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₅ and R₆ may be substituted with deuterium,
n is an integer from 0 to 2,
p, q and w are independently an integer from 1 to 4,

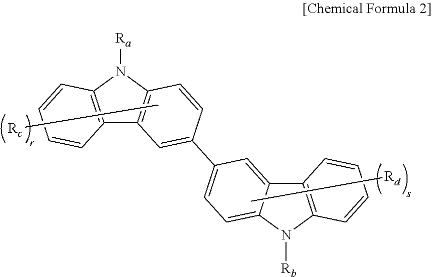

wherein in Chemical Formula 2,
each of Rₐ and R_{b} represents one selected from a group consisting of a C3-C40 monocyclic aryl group, a polycyclic aryl group, a monocyclic heteroaryl group, and a polycyclic heteroaryl group, wherein each of Rₐ and R_{b} may independently be substituted with at least one substituent selected from a group consisting of an alkyl group, an aryl group, a heteroaryl group, a cyano group, an alkylsilyl group, and an arylsilyl group such as triphenylsilyl group, each of R_{c} and R_{d} represents one selected from a group consisting of hydrogen, deuterium, halogen, a cyano group and an alkyl group, wherein each of r and s independently represents an integer from 0 to 7, wherein when r is 2 or more, each R_{c} in (R_{c})ᵣ is the same as or different from each other, wherein when s is 2 or more, each R_{d} in (R_{d})ₛ is the same as or different from each other,

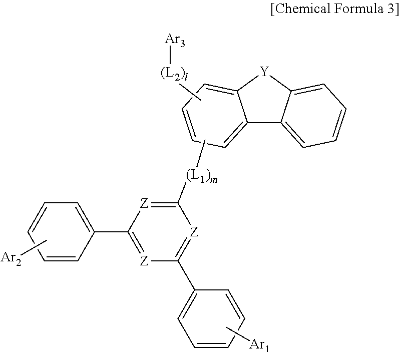

wherein in Chemical Formula 3,
each of Z_{S} independently represents nitrogen (N) or CR⁰, wherein at least two of Z_{S} are nitrogen (N),
R₀ represents one selected from a group consisting of hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Y represents either oxygen (O) or sulfur (S),
each of L₁ and L₂ independently represents selected from a group consisting of a single bond, an amino group, a nitrile group, a nitro group, an alkylene group, an alkenylene group, an alkynylene group, an oxyalkylene group, an oxyarylene group and an arylene group,
each of l and m independently represents an integer from 0 to 2,
each of Ar₁ and Ar₂ independently represents selected from a group consisting of hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Ar₃ represents a C6-C60 aryl group.

In the organic light-emitting device according to the present disclosure, the organometallic compound represented by Chemical Formula 1 may be used as a phosphorescent dopant, and the compound represented by Chemical Formula 2 and the compound represented by Chemical Formula 3 are mixed with each other to produce a mixture which may be used as a phosphorescent host. Thus, the operation voltage of the organic light-emitting device may be lowered and the efficiency, and lifetime characteristics thereof may be improved. Thus, low power consumption may be achieved.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a schematic cross-sectional view of an organic light-emitting diode according to an embodiment of the present disclosure.

FIG. 2 is a schematic cross-sectional view of an organic light-emitting diode having a tandem structure including two light-emitting stacks according to an embodiment of the present disclosure.

FIG. 3 is a cross-sectional view schematically showing an organic light-emitting diode of a tandem structure having three light-emitting stacks according to an embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “including,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to,” “before,” etc., another event may occur therebetween unless “directly after,” “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to,” or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unless otherwise stated herein, substituents not defined by a number of carbon atoms may contain up to 60 carbon atoms, and the minimum number of carbon atoms that may be included in each substituent is determined by what is known.

As used herein, “embodiments,” “examples,” “aspects, and the like should not be construed such that any aspect or design as described is superior to or advantageous over other aspects or designs.

Further, the term “or” means “inclusive or” rather than “exclusive or.” That is, unless otherwise stated or clear from the context, the expression that “x uses a or b” means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

As used herein, the term “halo” or “halogen” includes fluorine, chlorine, bromine and iodine.

The present disclosure may include all cases in which some or all of hydrogens of each of the organometallic compound represented by Chemical Formula 1, the compound represented by Chemical Formula 2, and the compound represented by Chemical Formula 3 are substituted with deuterium.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkene radicals and branched alkene radicals. Unless otherwise specified, the alkenyl group contains 2 to 20 carbon atoms. Additionally, the alkenyl group may be optionally substituted.

As used herein, the term “alkynyl group” refers to both linear alkyne radicals and branched alkyne radicals. Unless otherwise specified, the alkynyl group contains 2 to 20 carbon atoms. Additionally, the alkynyl group may be optionally substituted.

The terms “aralkyl group” and “arylalkyl group” as used herein are used interchangeably with each other and refer to an alkyl group having an aromatic group as a substituent. Further, the alkylaryl group may be optionally substituted.

The terms “aryl group” and “aromatic group” as used herein are used in the same meaning. The aryl group includes both a monocyclic group and a polycyclic group. The polycyclic group may include a “fused ring” in which two or more rings are fused with each other such that two carbons are common to two adjacent rings. Unless otherwise specified, the aryl group contains 6 to 60 carbon atoms. Further, the aryl group may be optionally substituted. Non-limiting examples of aryl group include phenyl, 1-naphthyl, 2-naphthyl, and biphenyl, fluorenyl, triphenylene, anthracene, phenanthrene, and phenalene.

The term “heterocyclic group” as used herein means that at least one of carbon atoms constituting an aryl group, a cycloalkyl group, or an aralkyl group (arylalkyl group) is substituted with a heteroatom such as oxygen (O), nitrogen (N), sulfur (S), etc. Further, the heterocyclic group may be optionally substituted.

The term “carbocyclic ring” as used herein may be used as a term including both “cycloalkyl group” as an alicyclic group and “aryl group” an aromatic group unless otherwise specified.

The terms “heteroalkyl group” and “heteroalkenyl group” as used herein mean that at least one of carbon atoms constituting the group is substituted with a heteroatom such as oxygen (O), nitrogen (N), or sulfur (S). In addition, the heteroalkyl group and the heteroalkenyl group may be optionally substituted.

As used herein, the term “substituted” means that a substituent other than hydrogen (H) binds to corresponding carbon, wherein the substituent may be the one selected from hydroxy, halogen, cyano, alkyl, alkoxy, fluorinated alkoxy, heteroaryl, heterocyclyl, alkylheterocyclyl, —NH₂, —NH(alkyl), —N(alkyl)₂, —NHC(O)(alkyl), —S(alkyl), —SO₂NH₂, —SO₂NH(alkyl), —SO₂N(alkyl)₂, —SO₂NH(cycloalkyl), —SO₂N(cycloalkyl)₂, —C(O)NH₂, —C(O)NH(alkyl), —C(O)N(alkyl)₂, —O-heterocyclyl, —O-heterocyclyl-alkylaryl, —SO₂NH(cycloalkyl), and —CO₂(alkyl).

Subjects and substituents as defined in the present disclosure may be the same as or different from each other unless otherwise specified.

Hereinafter, a structure of an organometallic compound according to the present disclosure and an organic light-emitting diode including the same will be described in detail.

Conventionally, an organometallic compound has been used as a dopant of a phosphorescent light-emissive layer. For example, a structure such as 2-phenylpyridine is known as a main ligand structure of an organometallic compound. However, such a conventional light-emitting dopant has limitations in improving the efficiency and lifetime of the organic light-emitting diode. Thus, it is desirable to develop a novel light-emitting dopant material. The present disclosure has been completed by experimentally confirming that when a mixture of a hole transport type host and an electron transport type host as host materials is used together with the novel dopant material, the efficiency and lifetime of the organic light-emitting diode are improved, and an operation voltage thereof is lowered, thereby improving the characteristics of the organic light-emitting diode.

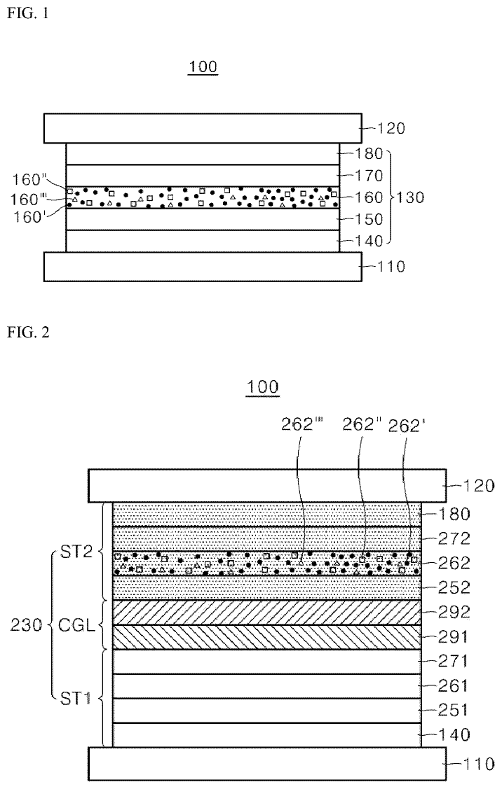

Specifically, referring to FIG. 1 according to one implementation of the present disclosure, an organic light-emitting diode 100 including a first electrode 10; a second electrode 120 facing the first electrode 110; and an organic layer 130 disposed between the first electrode 110 and the second electrode 120 may be provided. The organic layer 130 may include a light-emissive layer 160. The light-emissive layer 160 may include a dopant material 160′ and host materials 160″ and 160′″. The dopant material may include an organometallic compound 160′ represented by the following Chemical Formula 1. The host material may include a mixture of two types of host materials: a compound 160″ represented by the following Chemical Formula 2 as the hole transporting host material and a compound 160′″ represented by the following Chemical Formula 3 as the electron transporting host material:

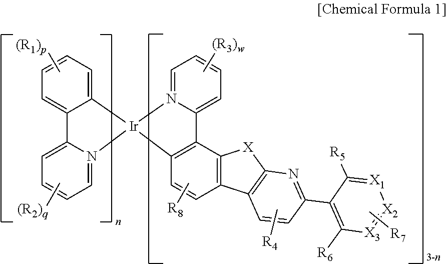

wherein in Chemical Formula 1,
X represents one selected from a group consisting of oxygen (O), sulfur (S) and selenium (Se),
each of X₁, X₂ and X₃ independently represents nitrogen (N) or CR′,
each of R₁, R₂, R₃, R₄, R₇, R₈ and R′ independently represents one selected from a group consisting of hydrogen, deuterium, halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₁, R₂, R₃, R₄, R₇, R₈ and R′ may be substituted with deuterium,
wherein each of R₅ and R₆ independently represents one selected from a group consisting of halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₅ and R₆ may be substituted with deuterium,
n is an integer from 0 to 2,
p, q and w are independently an integer from 1 to 4,

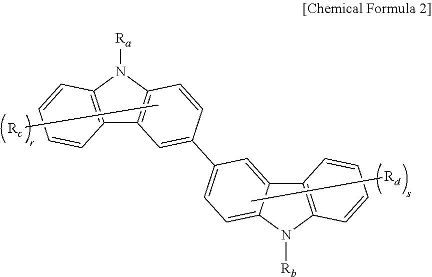

wherein in Chemical Formula 2,
each of Rₐ and R_{b} represents one selected from a group consisting of a C3-C40 monocyclic aryl group, a polycyclic aryl group, a monocyclic heteroaryl group, and a polycyclic heteroaryl group, wherein each of Rₐ and R_{b} may independently be substituted with at least one substituent selected from a group consisting of an alkyl group, an aryl group, a heteroaryl group, a cyano group, an alkylsilyl group, and an arylsilyl group such as triphenylsilyl group,
each of R_{c} and R_{d} represents one selected from a group consisting of hydrogen, deuterium, halogen, a cyano group and an alkyl group, wherein each of r and s independently represents an integer from 0 to 7, wherein when r is 2 or more, each R_{c} in (R_{c})ᵣ is the same as or different from each other, wherein when s is 2 or more, each R_{d} in (R_{d})ₛ is the same as or different from each other,

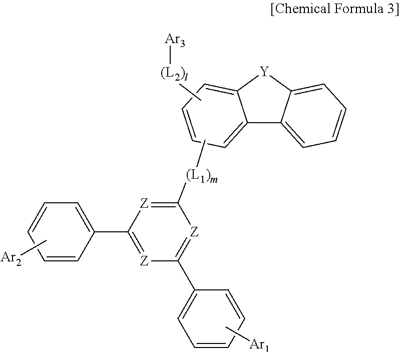

wherein in Chemical Formula 3,
each of Z_{S} independently represents nitrogen (N) or CR⁰, wherein at least two of Z_{S} are nitrogen (N),
R⁰ independently represents one selected from a group consisting of hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Y represents either oxygen (O) or sulfur (S),
each of L₁ and L₂ independently represents selected from a group consisting of a single bond, an amino group, a nitrile group, a nitro group, an alkylene group, an alkenylene group, an alkynylene group, an oxyalkylene group, an oxyarylene group and an arylene group,
each of l and m independently represents an integer from 0 to 2,
each of Ar₁ and Ar₂ independently represents selected from a group consisting of hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Ar₃ represents a C6-C60 aryl group.

According to one implementation of the present disclosure, the organometallic compound represented by Chemical Formula 1 may have a heteroleptic or homoleptic structure. For example, the organometallic compound represented by Chemical Formula 1 may have a homoreptic structure where n in Chemical Formula 1 is 0, a heteroleptic structure in which n in Chemical Formula 1 is 1, or a heteroleptic structure where n in Chemical Formula 1 is 2. In one example, n in Chemical Formula 1 may be 2.

According to one implementation of the present disclosure, X in the Chemical Formula 1 may be oxygen (O).

According to one implementation of the present disclosure, the organometallic compound represented by Chemical Formula 1 may comprises one selected from a group consisting of following compound GD-1 to compound GD-10. However, the specific example of the compound represented by Chemical Formula 1 of the present disclosure is not limited thereto as long as it meets the above definition of Chemical Formula 1:

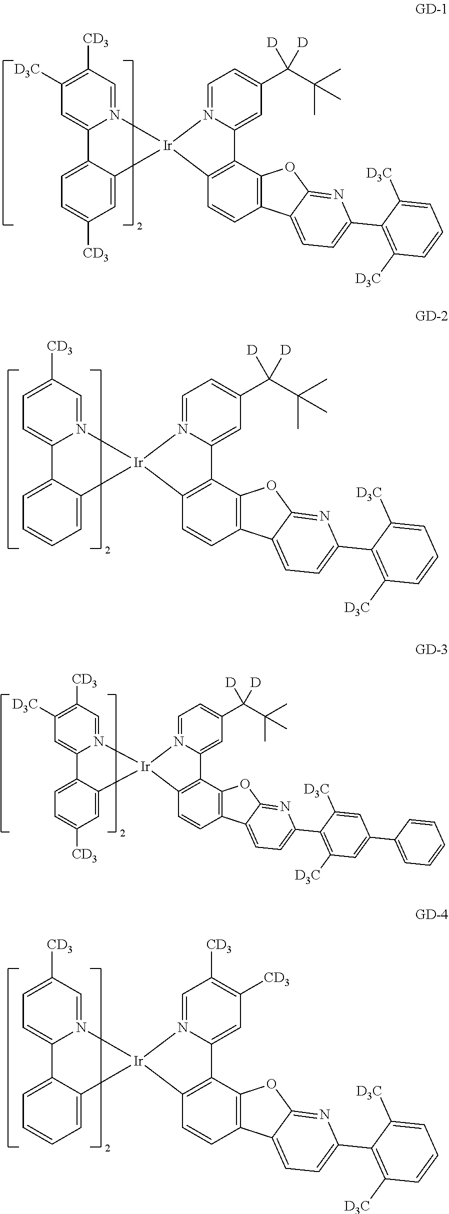

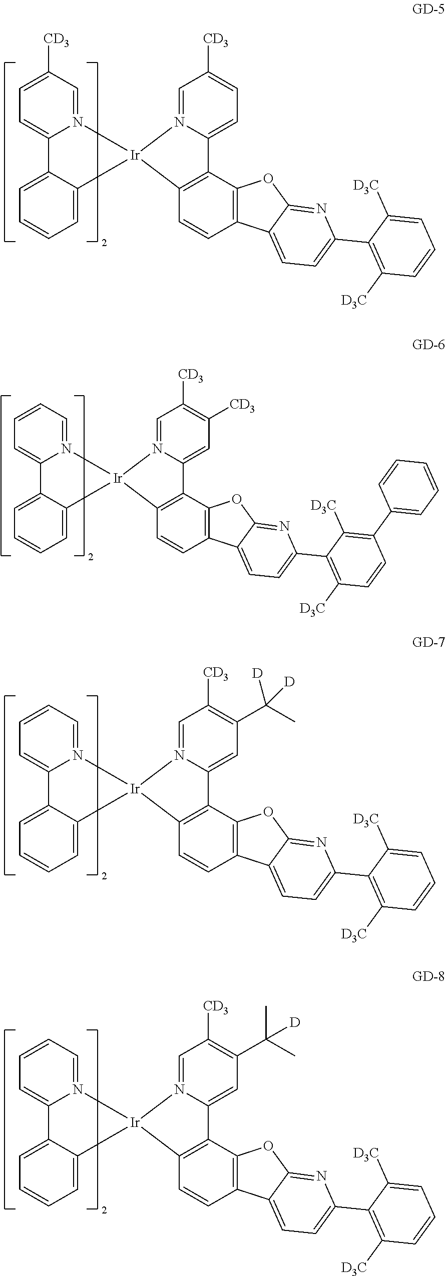

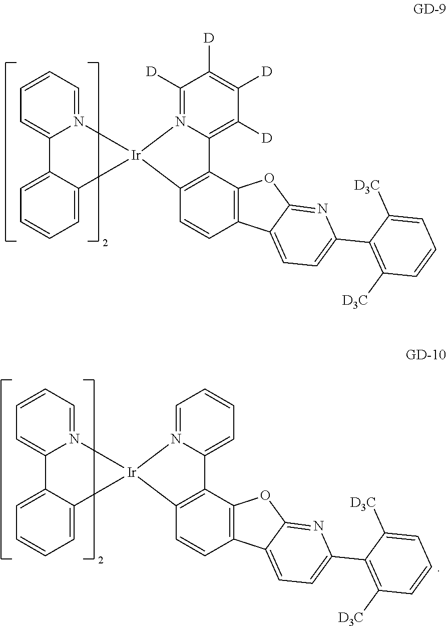

According to one implementation of the present disclosure, each of Rₐ and R_{b} of Chemical Formula 2 may be a C3-C40 monocyclic or polycyclic aryl group or heteroaryl group. Each of C3-C40 aryl group as each of Rₐ and R_{b} of Chemical Formula 2 may independently be substituted with one or more substituents selected from a group consisting of an alkyl group, an aryl group, a cyano group, an alkylsilyl group, and an arylsilyl group.

According to one implementation of the present disclosure, each of Rₐ and R_{b} may be preferably a monocyclic or polycyclic aryl group. The aryl group as each of Rₐ and R_{b} may be independently selected from a group consisting of a phenyl group, a naphthyl group, an anthracene group, a chrysene group, a pyrene group, a phenanthrene group, a triphenylene group, a fluorene group, and a 9,9′-spirofluorene group.

According to the implementation of the present disclosure, each of R_{c} and R_{d} of Chemical Formula 2 may be one selected from a group consisting of hydrogen, deuterium, halogen, a cyano group and an alkyl group. R_{c} and R_{d} may be the same as or different from each other. Preferably, both R_{c} and R_{d} may be hydrogen.

According to one implementation of the present disclosure, the compound represented by Chemical Formula 2 may be one selected from a group consisting of following compound GHH-1 to compound GHH-20. However, the specific example of the compound represented by Chemical Formula 2 of the present disclosure is not limited thereto as long as it meets the above definition of Chemical Formula 2:

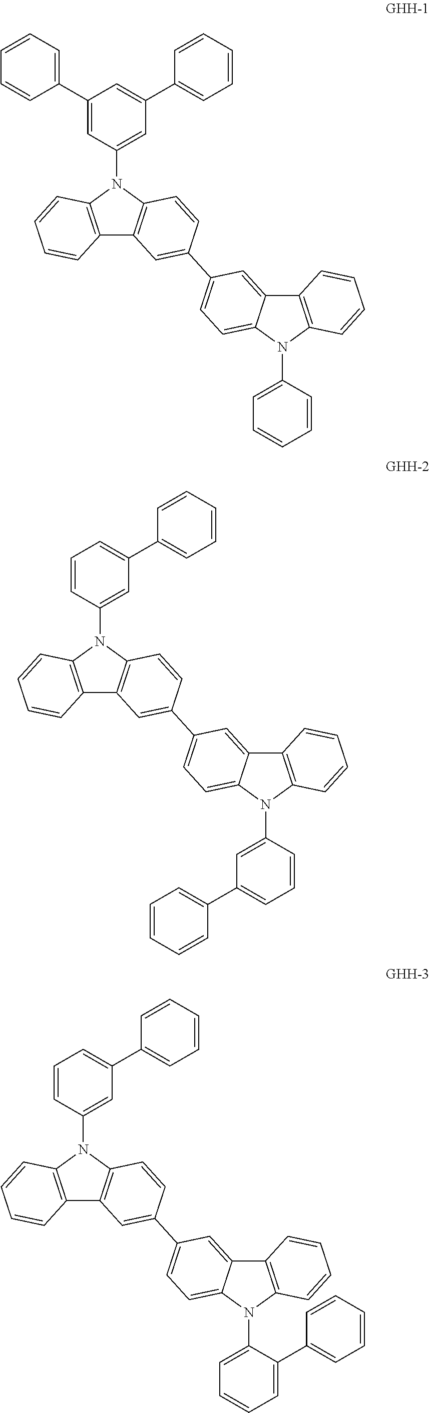

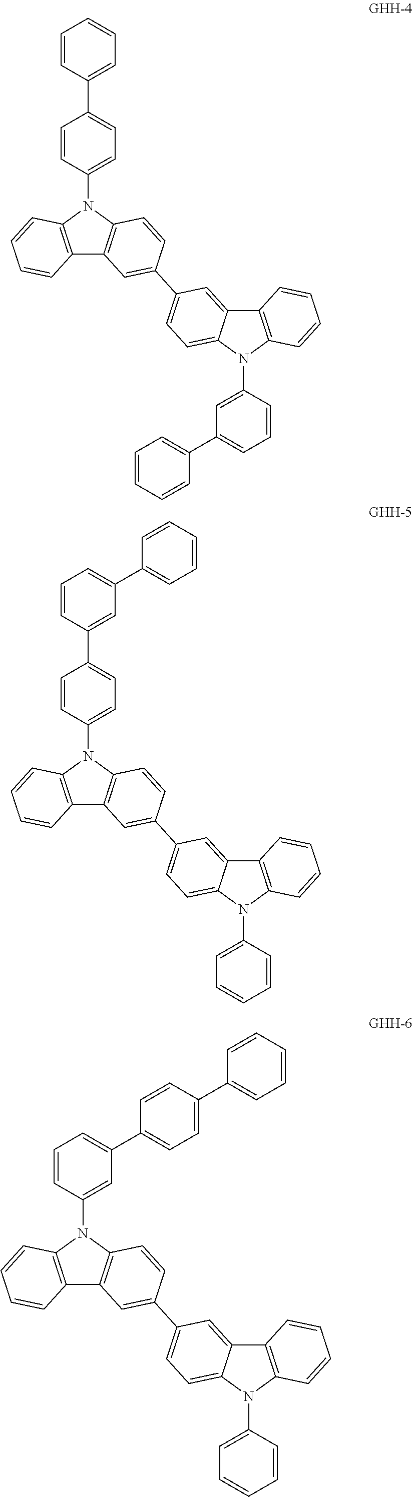

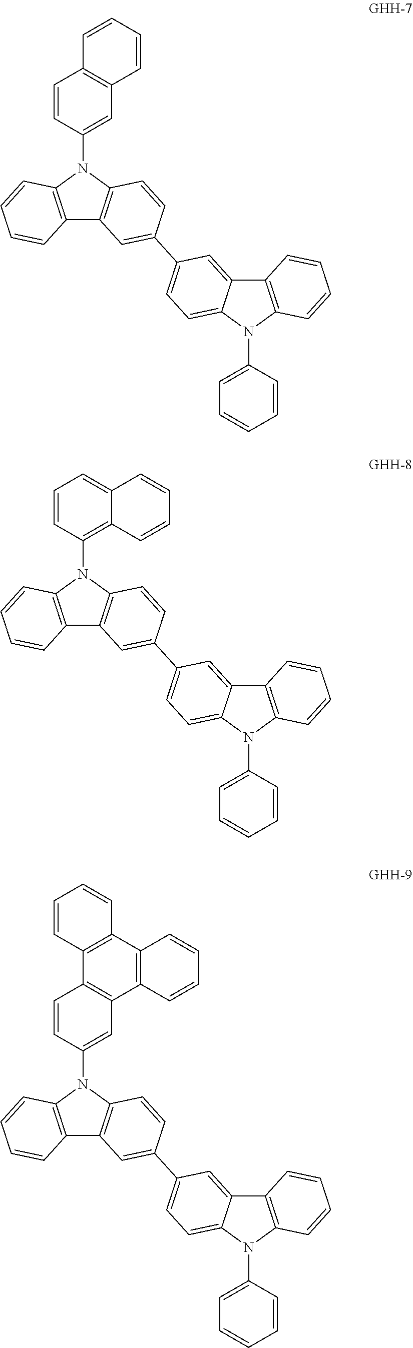 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

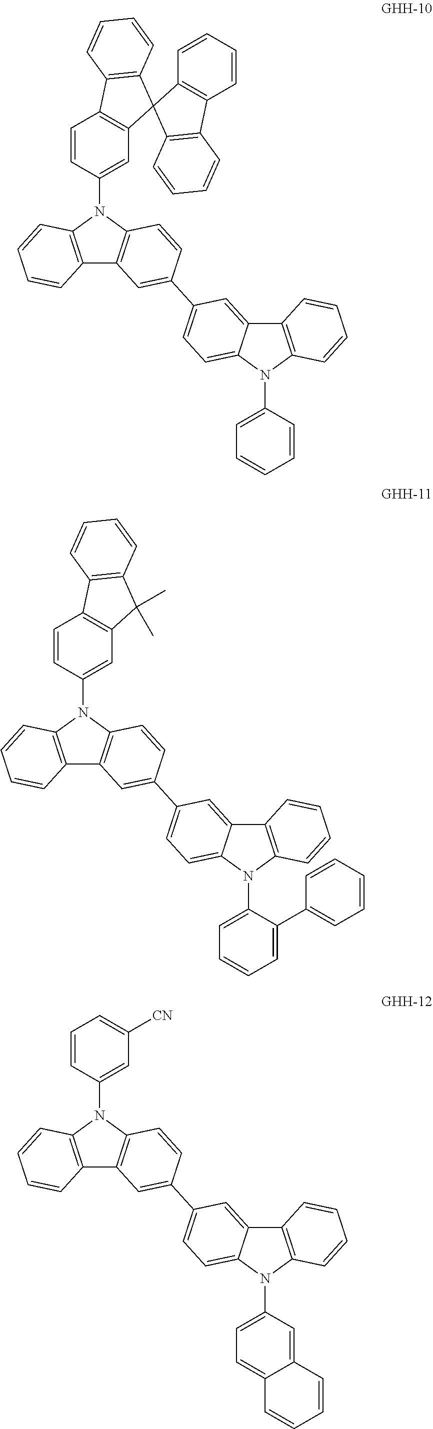 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

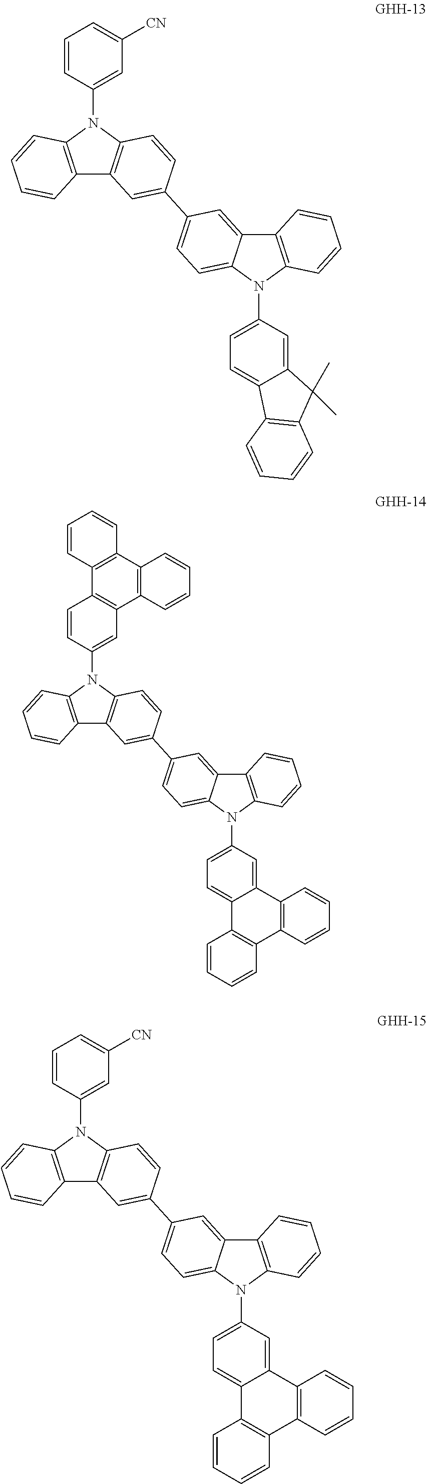 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

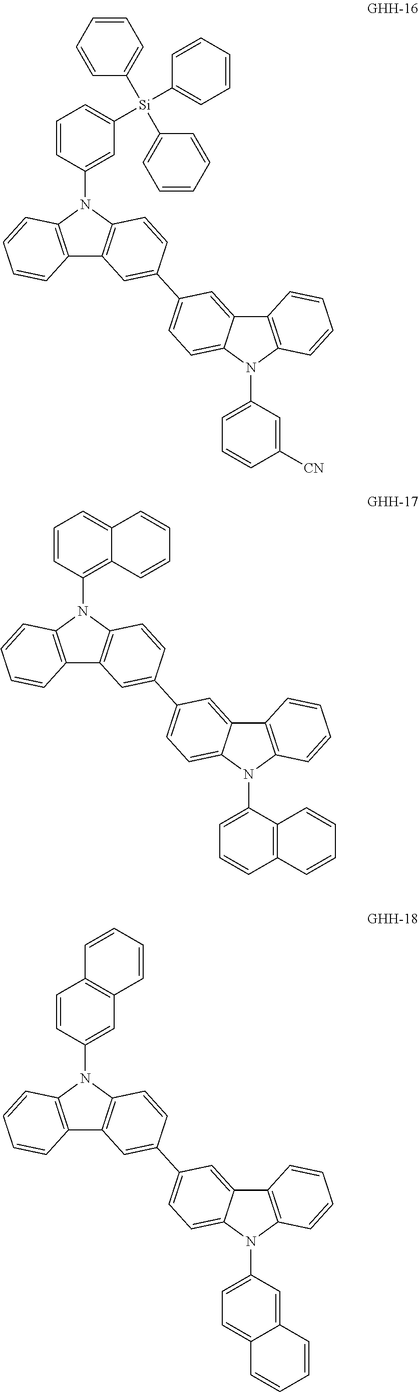 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

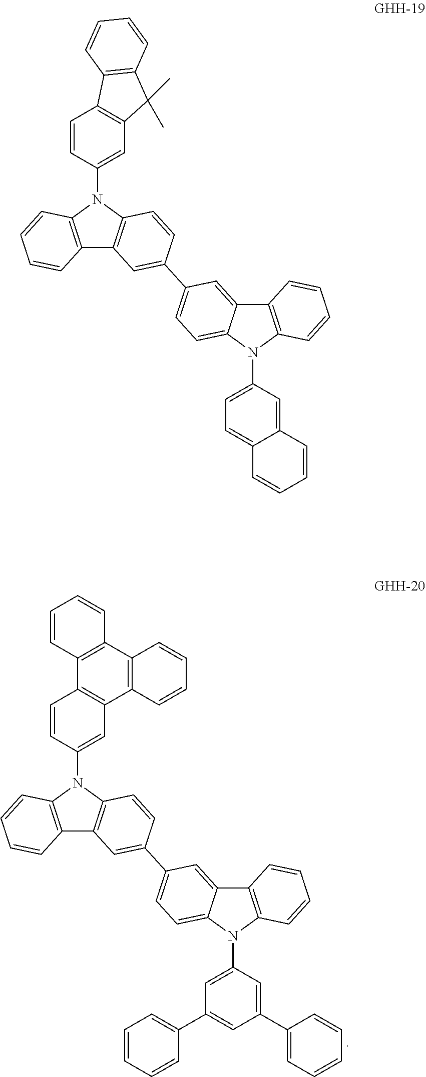 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1]

According to one implementation of the present disclosure, each of l and m of Chemical Formula 3 may independently represent 0 or 1.

According to one implementation of the present disclosure, each of Ar₁ and Ar₂ of Chemical Formula 3 may independently represent hydrogen or a C6-C50 aryl group.

According to one implementation of the present disclosure, Ar₃ of Chemical Formula 3 may be one selected from a group consisting of a phenyl group, a biphenyl group, a terphenyl group, a naphthyl group, an anthracenyl group, a phenanthryl group, a pyrenyl group, a perylenyl group, a chrysenyl group, and a substituted or unsubstituted fluorenyl group.

According to one implementation of the present disclosure, the compound represented by Chemical Formula 3 may be one selected from a group consisting of following compound GEH-1 to compound GEH-20. However, the specific example of the compound represented by Chemical Formula 3 of the present disclosure is not limited thereto as long as it meets the above definition of Chemical Formula 3:

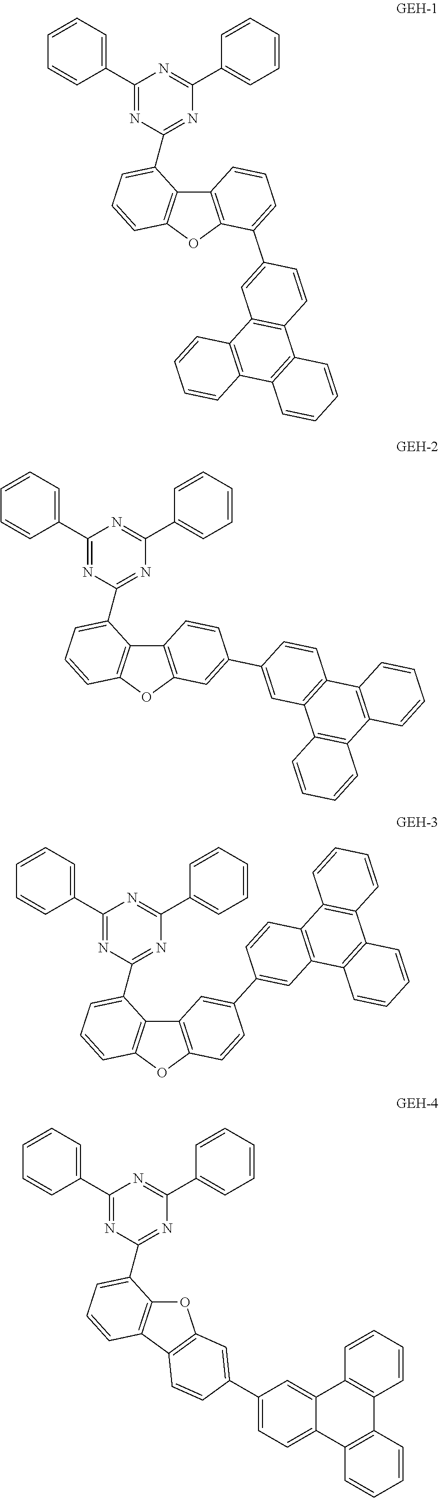 [SMILES: c1ccc(-c2nc(-c3ccccc3)nc(-c3cccc4oc5c(-c6ccc7c8ccccc8c8ccccc8c7c6)cccc5c34)n2)cc1 ; c1ccc(-c2nc(-c3ccccc3)nc(-c3cccc4oc5cc(-c6ccc7c8ccccc8c8ccccc8c7c6)ccc5c34)n2)cc1 ; c1ccc(-c2nc(-c3ccccc3)nc(-c3cccc4oc5ccc(-c6ccc7c8ccccc8c8ccccc8c7c6)cc5c34)n2)cc1 ; c1ccc(-c2nc(-c3ccccc3)nc(-c3cccc4c3oc3cc(-c5ccc6c7ccccc7c7ccccc7c6c5)ccc34)n2)cc1]

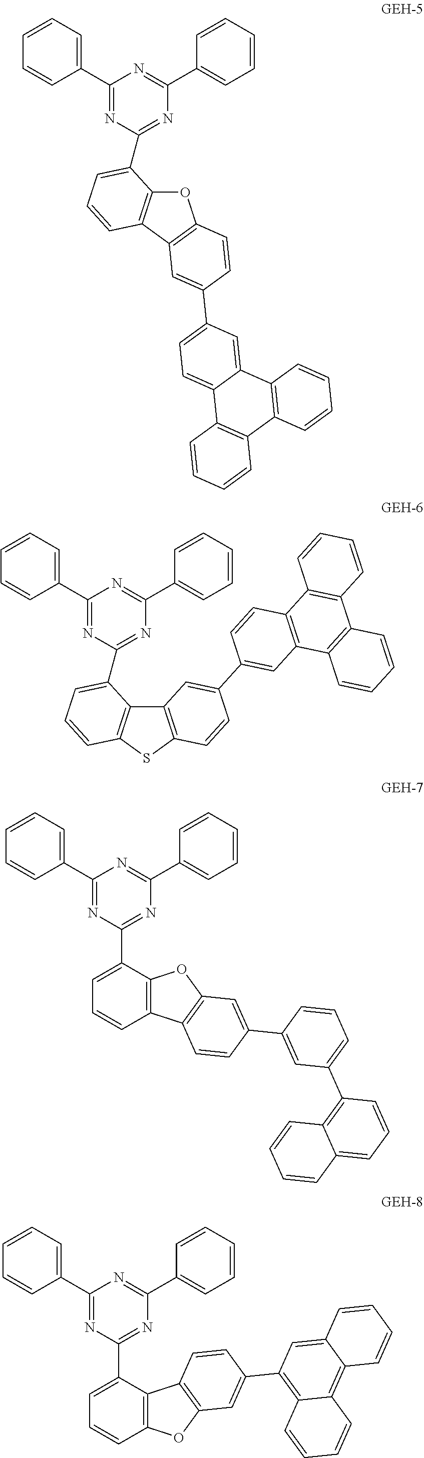 [SMILES: c1ccc(-c2nc(-c3ccccc3)nc(-c3cccc4c3oc3ccc(-c5ccc6c7ccccc7c7ccccc7c6c5)cc34)n2)cc1 ; c1ccc(-c2nc(-c3ccccc3)nc(-c3cccc4sc5ccc(-c6ccc7c8ccccc8c8ccccc8c7c6)cc5c34)n2)cc1 ; c1ccc(-c2nc(-c3ccccc3)nc(-c3cccc4c3oc3cc(-c5cccc(-c6cccc7ccccc67)c5)ccc34)n2)cc1 ; c1ccc(-c2nc(-c3ccccc3)nc(-c3cccc4oc5cc(-c6cc7ccccc7c7ccccc67)ccc5c34)n2)cc1]

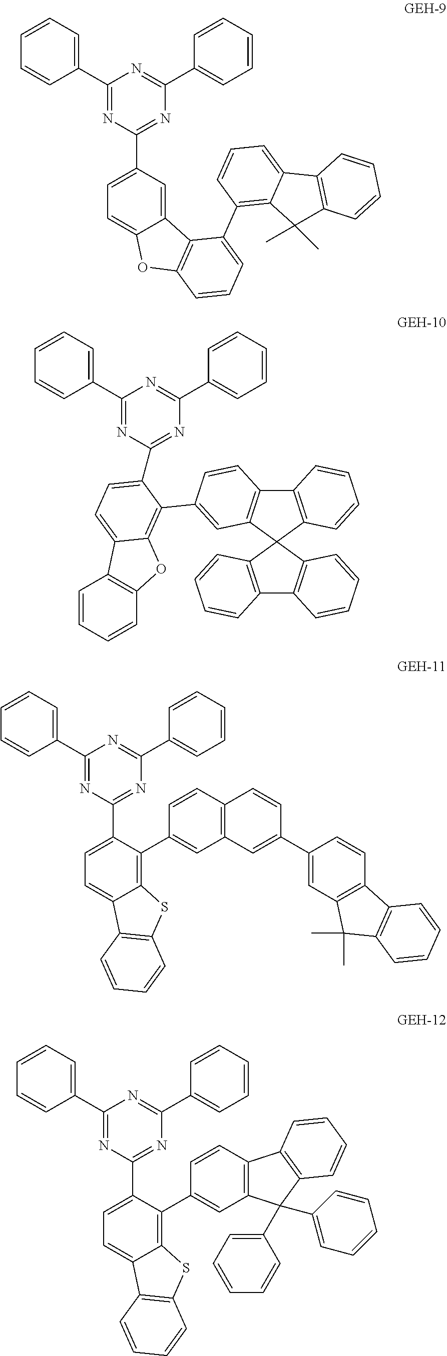

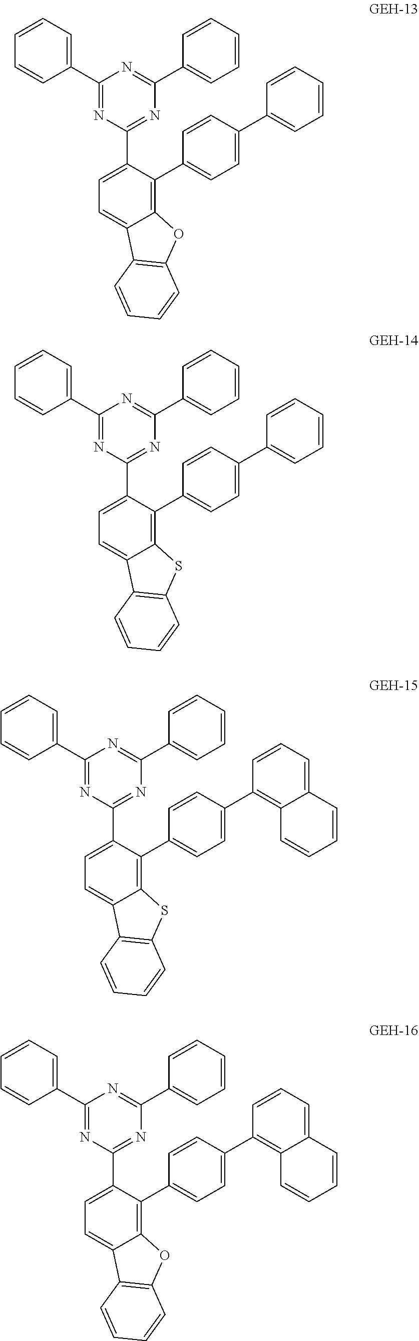 [SMILES: c1ccc(-c2ccc(-c3c(-c4nc(-c5ccccc5)nc(-c5ccccc5)n4)ccc4c3oc3ccccc34)cc2)cc1 ; c1ccc(-c2ccc(-c3c(-c4nc(-c5ccccc5)nc(-c5ccccc5)n4)ccc4c3sc3ccccc34)cc2)cc1 ; c1ccc(-c2nc(-c3ccccc3)nc(-c3ccc4c(sc5ccccc54)c3-c3ccc(-c4cccc5ccccc45)cc3)n2)cc1 ; c1ccc(-c2nc(-c3ccccc3)nc(-c3ccc4c(oc5ccccc54)c3-c3ccc(-c4cccc5ccccc45)cc3)n2)cc1]

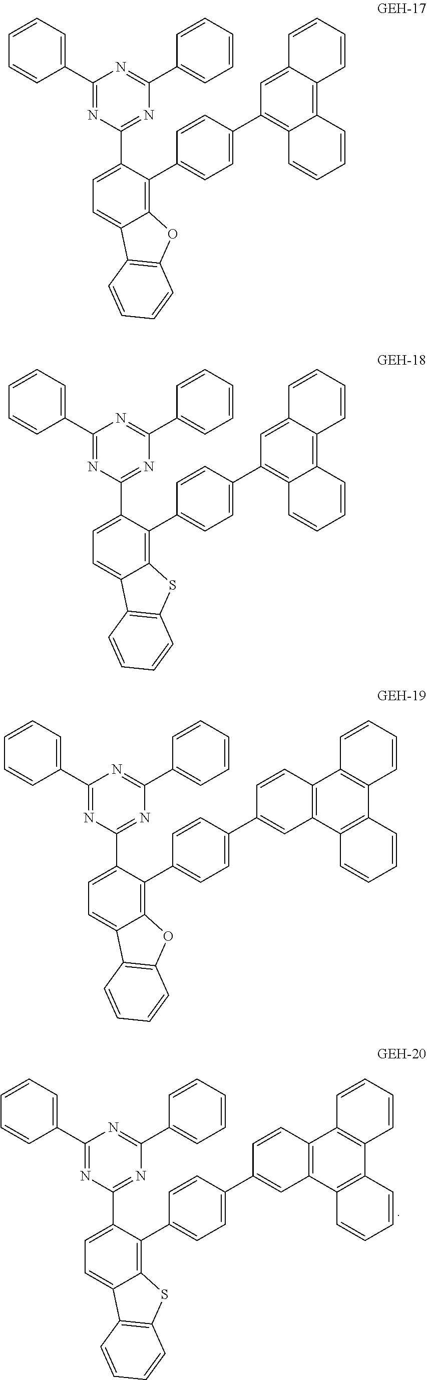 [SMILES: c1ccc(-c2nc(-c3ccccc3)nc(-c3ccc4c(oc5ccccc54)c3-c3ccc(-c4cc5ccccc5c5ccccc45)cc3)n2)cc1 ; c1ccc(-c2nc(-c3ccccc3)nc(-c3ccc4c(sc5ccccc54)c3-c3ccc(-c4cc5ccccc5c5ccccc45)cc3)n2)cc1 ; c1ccc(-c2nc(-c3ccccc3)nc(-c3ccc4c(oc5ccccc54)c3-c3ccc(-c4ccc5c6ccccc6c6ccccc6c5c4)cc3)n2)cc1 ; c1ccc(-c2nc(-c3ccccc3)nc(-c3ccc4c(sc5ccccc54)c3-c3ccc(-c4ccc5c6ccccc6c6ccccc6c5c4)cc3)n2)cc1]

In addition, in the organic light-emitting diode 100, the organic layer 130 disposed between the first electrode 110 and the second electrode 120 may be formed by sequentially stacking a hole injection layer 140 (HIL), a hole transport layer 150, (HTL), a light emission layer 160 (EML), an electron transport layer 170 (ETL) and an electron injection layer 180 (EIL) on the first electrode 110. The second electrode 120 may be formed on the electron injection layer 180, and a protective layer (not shown) may be formed thereon.

Further, although not shown in FIG. 1, a hole transport auxiliary layer may be further added between the hole transport layer 150 and the light-emitting layer 160. The hole transport auxiliary layer may contain a compound having good hole transport properties, and may reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 may be reduced, thereby reducing a quenching phenomenon in which excitons disappear at the interface due to polarons. Accordingly, deterioration of the element may be reduced, and the element may be stabilized, thereby improving efficiency and lifespan thereof.

The first electrode 110 may act as a positive electrode, and may be made of ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combination thereof. However, the present disclosure is not limited thereto.

The hole injection layer 140 may be positioned between the first electrode 110 and the hole transport layer 150. The hole injection layer 140 may have a function of improving interface characteristics between the first electrode 110 and the hole transport layer 150, and may be selected from a material having appropriate conductivity. The hole injection layer 140 may include a compound selected from a group consisting of MTDATA (m-MTDATA: 4,4′,4″-Tris[phenyl(m-tolyl)amino]triphenylamine), CuPc (Copper(II) phthalocyanine), TCTA (tris(4-carbazoyl-9-ylphenyl)amine), HATCN (1,4,5,8,9,11-Hexaazatriphenylenehexacarbonitrile), TDAPB (1,3,5-Tris[4-[bis(4-methoxyphenyl)amino]phenyl]benzene), PEDOT/PSS (poly(3,4-ethylenedioxythiophene) polystyrene sulfonate), and N1,N1′-([1,1′-biphenyl]-4,4′-diyl)bis(N1,N4,N4)-triphenylbenzene-1,4-diamine). Preferably, the hole injection layer 140 may include N1,N1′-([1,1′-biphenyl]-4,4′-diyl)bis(N1,N4,N4-triphenylbenzene-1,4-diamine). However, the present disclosure is limited thereto.

The hole transport layer 150 may be positioned adjacent to the light-emitting layer and between the first electrode 110 and the light-emitting layer 160. A material of the hole transport layer 150 may include a compound selected from a group consisting of TPD (N,N′-Bis(3-methylphenyl)-N,N′-diphenylbenzidine), NPB (N,N′-Di(1-naphthyl)-N,N′-diphenyl-(1,1′-biphenyl)-4,4′-diamine), CBP (4,4′-Bis(N-carbazolyl)-1,1′-biphenyl), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. Preferably, the material of the hole transport layer 150 may include NPB. However, the present disclosure is not limited thereto.

According to one implementation of the present disclosure, the light-emitting layer 160 may be formed by doping the mixture of the host materials 160″ and 160′″ with the organometallic compound represented by Chemical Formula 1 as the dopant 160′ in order to improve luminous efficiency of the diode 100. The dopant 160′ may be used as a green or red light-emitting material, and preferably as a green phosphorescent material.

According to one implementation of the present disclosure, a doping concentration of the dopant 160′ may be adjusted to be within a range of 1 to 30% by weight based on a total weight of the mixture of the two host materials 160″ and 160′″. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

According to one implementation of the present disclosure, the mixing ratio of the two types of hosts 160″ and 160′″ is not particularly limited. The host 160″ which is the compound represented by Chemical Formula 2 has hole transport properties. The host 160″ which is the compound represented by Chemical Formula 3 has electron transport characteristics. Thus, the mixture of the two kinds of hosts can achieve the advantage of increasing the lifespan characteristics of the element. The mixing ratio of the two types of hosts may be appropriately adjusted. Therefore, the mixing ratio of the two hosts, that is, the compound represented by Chemical Formula 2 and the compound represented by Chemical Formula 3 is not particularly limited. The mixing ratio (based on a weight) of the compound represented by Chemical Formula 2 and the compound represented by Chemical Formula 3 may be, for example, in a range of 1:9 to 9:1, for example, may be 2:8, for example, may be 3:7, for example, may be 4:6, for example, may be 5:5, for example, may be 6:4, for example, may be 7:3, for example, may be 8:2.

Further, the electron transport layer 170 and the electron injection layer 180 may be sequentially stacked between the light-emitting layer 160 and the second electrode 120. A material of the electron transport layer 170 has high electron mobility such that electrons may be stably supplied to the light-emitting layer under smooth electron transport.

For example, the material of the electron transport layer 170 may be known to the art and may include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, and 2-(4-(9,10-di(naphthalen-2-yl)anthracen-2-yl)phenyl)-1-phenyl-1H-benzo[d]imidazole. Preferably, the material of the electron transport layer 170 may include 2-(4-(9,10-di(naphthalen-2-yl)anthracen-2-yl)phenyl)-1-phenyl-1H-benzo[d]imidazole. However, the present disclosure is not limited thereto.

The electron injection layer 180 serves to facilitate electron injection. A material of the electron injection layer may be known to the art and may include a compound selected from a group consisting of Alq3 (tris(8-hydroxy quinolino)aluminum), PBD, TAZ, spiro-PBD, BAlq, SAlq, etc. However, the present disclosure is not limited thereto. Alternatively, the electron injection layer 180 may be made of a metal compound. The metal compound may include, for example, one or more selected from a group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to an illustrative embodiment of the present disclosure may be formed in a structure in which adjacent ones of two or more light-emitting stacks are connected to each other via a charge generation layer (CGL). The organic light-emitting diode may include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

In this case, the light-emitting layer included in at least one of the plurality of light-emitting stacks may contain the organometallic compound represented by Chemical Formula 1 according to the present disclosure as the dopants. Adjacent ones of the plurality of light-emitting stacks in the tandem structure may be connected to each other via the charge generation layer CGL including an N-type charge generation layer and a P-type charge generation layer.

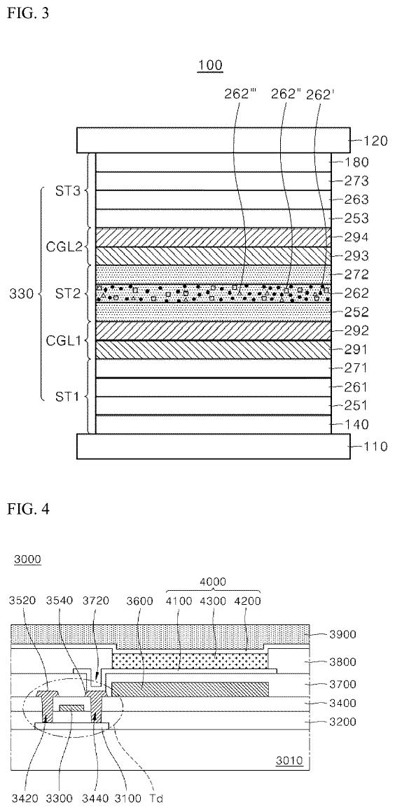

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by Chemical Formula 1 according to the present disclosure as the dopants 262′. For example, as shown in FIG. 2, the second light-emissive layer 262 of the second light-emitting stack ST2 may include a compound 262′ represented by Chemical Formula 1 as a dopant, a compound 262″ represented by Chemical Formula 2 as a hole transporting host, and a compound 262′″ represented by Chemical Formula 3 as an electron transporting host. Although not shown in FIG. 2, each of the first and second light-emitting stacks ST1 and ST2 may further include an additional light-emissive layer in addition to each of the first light-emissive layer 261 and the second light-emissive layer 262. The descriptions as set forth above with respect to the hole transport layer 150 of FIG. 1 may be applied in the same or similar manner to each of the first hole transport layer 251 and the second hole transport layer 252 of FIG. 2. Moreover, the descriptions as set forth above with respect to the electron transport layer 170 of FIG. 1 may be applied in the same or similar manner to each of the first electron transport layer 271 and the second electron transport layer 272 of FIG. 2.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may contain the organometallic compound represented by Chemical Formula 1 according to the present disclosure as the dopants. For example, as shown in FIG. 3, the second light-emissive layer 262 of the second light-emitting stack ST2 may include the compound 262′ represented by Chemical Formula 1 as a dopant, the compound 262″ represented by Chemical Formula 2 as a hole transporting host, and the compound 262′″ represented by Chemical Formula 3 as an electron transporting host. Although not shown in FIG. 3, each of the first, second and third light-emitting stacks ST1, ST2 and ST3 may further include an additional light-emitting layer, in addition to each of the first light-emitting layer 261, the second light-emitting layer 262 and the third light-emitting layer 263. The descriptions as set forth above with respect to the hole transport layer 150 of FIG. 1 may be applied in the same or similar manner to each of the first hole transport layer 251, the second hole transport layer 252, and the third hole transport layer 253 of FIG. 3. Moreover, the descriptions as set forth above with respect to the electron transport layer 170 of FIG. 1 may be applied in the same or similar manner to each of the first electron transport layer 271, the second electron transport layer 272, and the third electron transport layer 273 of FIG. 3.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on the substrate 3010 and may be made of an oxide semiconductor material or polycrystalline silicon. When the semiconductor layer 3100 is made of an oxide semiconductor material, a light-shielding pattern (not shown) may be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 may be made of polycrystalline silicon. In this case, both edges of the semiconductor layer 3100 may be doped with impurities.

The gate insulating layer 3200 made of an insulating material is formed over an entirety of a surface of the substrate 3010 and on the semiconductor layer 3100. The gate insulating layer 3200 may be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 may be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of amorphous silicon. In one example, the switching thin-film transistor (not shown) may have substantially the same structure as that of the driving thin-film transistor (Td).

In one example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In this case, red, green, and blue color filter patterns that absorb light may be formed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 μm.

In one example, a planarization layer 3700 having a drain contact hole 3720 defined therein exposing the drain electrode 3540 of the driving thin-film transistor Td is formed to cover the driving thin-film transistor Td.

On the planarization layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of a conductive material having a relatively large work function value. For example, the first electrode 4100 may be made of a transparent conductive material such as ITO, IZO or ZnO.

In one example, when the organic light-emitting display device 3000 is of a top-emission type, a reflective electrode or a reflective layer may be further formed under the first electrode 4100. For example, the reflective electrode or the reflective layer may be made of one of aluminum (Al), silver (Ag), nickel (Ni), and an aluminum-palladium-copper (APC) alloy.

A bank layer 3800 covering an edge of the first electrode 4100 is formed on the planarization layer 3700. The bank layer 3800 exposes a center of the first electrode 4100 corresponding to the pixel area.

An organic layer 4300 is formed on the first electrode 4100. Optionally, the organic light-emitting diode 4000 may have a tandem structure. Regarding the tandem structure, reference may be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and may be used as a negative electrode (a cathode). For example, the second electrode 4200 may be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Present Example of the present disclosure will be described. However, following Present Example is only one example of the present disclosure. The present disclosure is not limited thereto.

### EXAMPLES

### Present Example 1

A glass substrate having a thin film of ITO (indium tin oxide) having a thickness of 1,000 Å coated thereon was washed, followed by ultrasonic cleaning with a solvent such as isopropyl alcohol, acetone, or methanol. Then, the glass substrate was dried. Thus, an ITO transparent electrode was formed.

HI-1 as a hole injection material was deposited on the ITO transparent electrode in a thermal vacuum deposition manner. Thus, a hole injection layer having a thickness of 100 nm was formed. Then, HT-1 as a hole transport material was deposited on the hole injection layer in a thermal vacuum deposition manner. Thus, a hole transport layer having a thickness of 350 nm was formed. Then, GD-1 was used as a dopant of a light-emitting layer and a mixture of GHH-1 and GEH-1 (GHH-1:GEH-1=7:3 based on a weight) was used as a host. The host material mixture was deposited on the hole transport layer in a thermal vacuum deposition manner. The dopant was doped into the host material mixture at a doping concentration of 10%. Thus, the light-emitting layer of a thickness of 400 nm was formed. Each of ET-1 and Liq (1:1) as a material of each of an electron transport layer and an electron injection layer was deposited on the light-emitting layer. Then, 100 nm thick aluminum was deposited thereon to form a negative electrode. In this way, an organic light-emitting diode was manufactured.

The materials used in Present Example 1 are as follows.

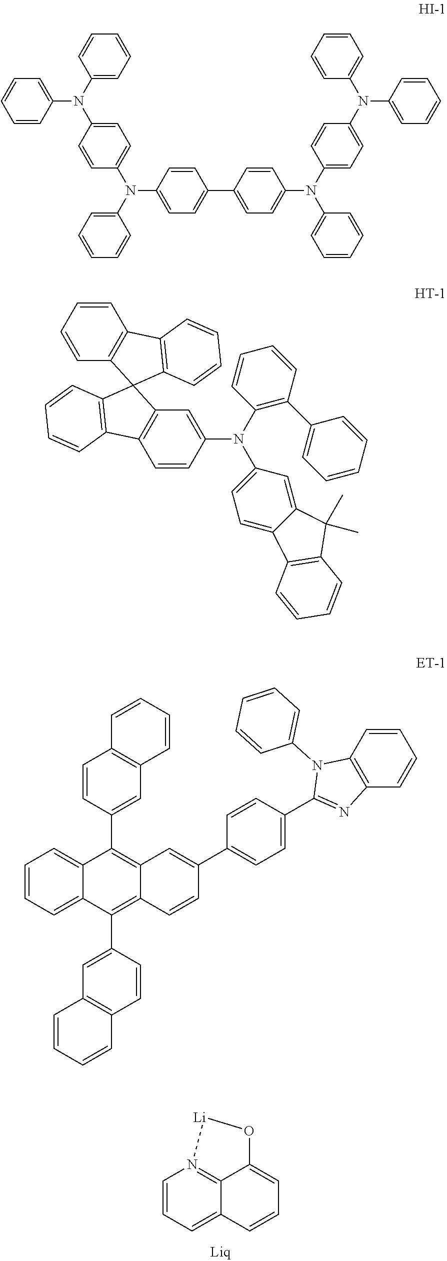

HI-1 is NPNPB (N,N′-diphenyl-N,N′-di-[4-(N,N-diphenyl-amino)phenyl]benzidine), and ET-1 is ZADN (2-[4-(9,10-Di-naphthalen-2-yl-anthracen-2-yl)-phenyl]-1-phenyl-1H-benzoimidazole).

### Comparative Examples 1 to 5, and Present Examples 2 to 200

An organic light-emitting diode each of Comparative Examples 1 to 5, and Present Examples 2 to 200 was manufactured in the same manner as in Present Example 1, except that the dopant materials and the host materials as described in following Tables 1 to 15 were used instead of the dopant material and the host materials in Present Example 1. In each of Comparative Examples 1 to 5, CBP having a following structure was used as a host.

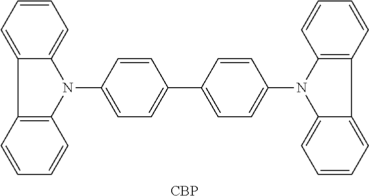 [SMILES: c1ccc2c(c1)c1ccccc1n2-c1ccc(-c2ccc(-n3c4ccccc4c4ccccc43)cc2)cc1 ; "CBP"]

### Experimental Example

The organic light-emitting diode as manufactured in each of Present Examples 1 to 200 and Comparative Examples 1 to 5 was connected to an external power source, and characteristics of the organic light-emitting diode were evaluated at room temperature using a current source and a photometer.

Specifically, operation voltage (V), external quantum efficiency (EQE; %), and lifetime characteristics (LT95; %) were measured at a current of 10 mA/cm², and were calculated as relative values to those of one of Comparative Examples 1 to 5, and the results are shown in the following Tables 1 to 15.

LT95 lifetime refers to a time it takes for the display element to lose 5% of its initial brightness. LT95 is the customer specification to most difficult to meet. Whether or not image burn-in occurs on the display may be determined based on the LT95.

TABLE 1

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-1 | GEH-1 | 4.15 | 119 | 121 |
| Example 1 | | | | | | |
| Present | GD-1 | GHH-1 | GEH-2 | 4.13 | 122 | 120 |
| Example 2 | | | | | | |
| Present | GD-1 | GHH-1 | GEH-3 | 4.10 | 119 | 119 |
| Example 3 | | | | | | |
| Present | GD-1 | GHH-1 | GEH-4 | 4.12 | 115 | 118 |
| Example 4 | | | | | | |
| Present | GD-1 | GHH-1 | GEH-5 | 4.10 | 118 | 116 |
| Example 5 | | | | | | |
| Present | GD-1 | GHH-1 | GEH-6 | 4.12 | 115 | 115 |
| Example 6 | | | | | | |
| Present | GD-1 | GHH-1 | GEH-7 | 4.11 | 111 | 112 |
| Example 7 | | | | | | |
| Present | GD-1 | GHH-1 | GEH-8 | 4.15 | 113 | 111 |
| Example 8 | | | | | | |
| Present | GD-1 | GHH-1 | GEH-9 | 4.14 | 111 | 109 |
| Example 9 | | | | | | |
| Present | GD-1 | GHH-1 | GEH-10 | 4.15 | 107 | 109 |
| Example 10 | | | | | | |
| Present | GD-1 | GHH-2 | GEH-1 | 4.13 | 120 | 118 |
| Example 11 | | | | | | |
| Present | GD-1 | GHH-2 | GEH-2 | 4.12 | 125 | 121 |
| Example 12 | | | | | | |
| Present | GD-1 | GHH-2 | GEH-3 | 4.08 | 130 | 135 |
| Example 13 | | | | | | |
| Present | GD-1 | GHH-2 | GEH-4 | 4.09 | 123 | 124 |
| Example 14 | | | | | | |
| Present | GD-1 | GHH-2 | GEH-5 | 4.07 | 122 | 126 |
| Example 15 | | | | | | |

TABLE 2

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-2 | GEH-6 | 4.07 | 121 | 124 |
| Example 16 | | | | | | |
| Present | GD-1 | GHH-2 | GEH-7 | 4.16 | 116 | 114 |
| Example 17 | | | | | | |
| Present | GD-1 | GHH-2 | GEH-8 | 4.15 | 118 | 116 |
| Example 18 | | | | | | |
| Present | GD-1 | GHH-2 | GEH-9 | 4.11 | 120 | 119 |
| Example 19 | | | | | | |
| Present | GD-1 | GHH-2 | GEH-10 | 4.12 | 116 | 115 |
| Example 20 | | | | | | |
| Present | GD-1 | GHH-3 | GEH-1 | 4.09 | 125 | 123 |
| Example 21 | | | | | | |
| Present | GD-1 | GHH-3 | GEH-2 | 4.10 | 120 | 119 |
| Example 22 | | | | | | |
| Present | GD-1 | GHH-3 | GEH-3 | 4.09 | 122 | 121 |
| Example 23 | | | | | | |
| Present | GD-1 | GHH-3 | GEH-4 | 4.10 | 121 | 118 |
| Example 24 | | | | | | |
| Present | GD-1 | GHH-3 | GEH-5 | 4.09 | 125 | 121 |
| Example 25 | | | | | | |
| Present | GD-1 | GHH-3 | GEH-6 | 4.08 | 122 | 120 |
| Example 26 | | | | | | |
| Present | GD-1 | GHH-3 | GEH-7 | 4.13 | 110 | 109 |
| Example 27 | | | | | | |
| Present | GD-1 | GHH-3 | GEH-8 | 4.12 | 120 | 115 |
| Example 28 | | | | | | |
| Present | GD-1 | GHH-3 | GEH-9 | 4.11 | 117 | 114 |
| Example 29 | | | | | | |
| Present | GD-1 | GHH-3 | GEH-10 | 4.17 | 106 | 104 |
| Example 30 | | | | | | |

TABLE 3

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-4 | GEH-1 | 4.11 | 119 | 117 |
| Example 31 | | | | | | |
| Present | GD-1 | GHH-4 | GEH-2 | 4.10 | 120 | 118 |
| Example 32 | | | | | | |
| Present | GD-1 | GHH-4 | GEH-3 | 4.13 | 114 | 116 |
| Example 33 | | | | | | |
| Present | GD-1 | GHH-4 | GEH-4 | 4.12 | 112 | 110 |
| Example 34 | | | | | | |
| Present | GD-1 | GHH-4 | GEH-5 | 4.11 | 114 | 113 |
| Example 35 | | | | | | |
| Present | GD-1 | GHH-4 | GEH-6 | 4.13 | 115 | 114 |
| Example 36 | | | | | | |
| Present | GD-1 | GHH-4 | GEH-7 | 4.15 | 106 | 103 |
| Example 37 | | | | | | |
| Present | GD-1 | GHH-4 | GEH-8 | 4.14 | 108 | 106 |
| Example 38 | | | | | | |
| Present | GD-1 | GHH-4 | GEH-9 | 4.16 | 109 | 107 |
| Example 39 | | | | | | |
| Present | GD-1 | GHH-4 | GEH-10 | 4.19 | 101 | 105 |
| Example 40 | | | | | | |
| Present | GD-1 | GHH-5 | GEH-1 | 4.09 | 118 | 114 |
| Example 41 | | | | | | |
| Present | GD-1 | GHH-5 | GEH-2 | 4.07 | 120 | 118 |
| Example 42 | | | | | | |
| Present | GD-1 | GHH-5 | GEH-3 | 4.08 | 116 | 116 |
| Example 43 | | | | | | |
| Present | GD-1 | GHH-5 | GEH-4 | 4.06 | 113 | 115 |
| Example 44 | | | | | | |
| Present | GD-1 | GHH-5 | GEH-5 | 4.05 | 114 | 116 |
| Example 45 | | | | | | |

TABLE 4

| | | | | | EQE | LT95 |
|---|---|---|---|---|---|---|
| | | | | Operation | (%, | (%, |
| | Light-emissive layer | | | voltage | relative | relative |
| | Dopant | Host | | (V) | value) | value) |
| Comparative | GD-1 | CBP | | 4.30 | 100 | 100 |
| Example 1 | | | | | | |
| Present | GD-1 | GHH-5 | GEH-6 | 4.06 | 116 | 115 |
| Example 46 | | | | | | |
| Present | GD-1 | GHH-5 | GEH-7 | 4.09 | 106 | 103 |
| Example 47 | | | | | | |
| Present | GD-1 | GHH-5 | GEH-8 | 4.08 | 107 | 106 |
| Example 48 | | | | | | |
| Present | GD-1 | GHH-5 | GEH-9 | 4.09 | 109 | 107 |
| Example 49 | | | | | | |
| Present | GD-1 | GHH-5 | GEH-10 | 4.13 | 103 | 101 |
| Example 50 | | | | | | |
| Present | GD-1 | GHH-6 | GEH-1 | 4.08 | 120 | 120 |
| Example 51 | | | | | | |
| Present | GD-1 | GHH-6 | GEH-2 | 4.07 | 121 | 119 |
| Example 52 | | | | | | |
| Present | GD-1 | GHH-6 | GEH-3 | 4.09 | 118 | 117 |
| Example 53 | | | | | | |
| Present | GD-1 | GHH-6 | GEH-4 | 4.10 | 117 | 115 |
| Example 54 | | | | | | |
| Present | GD-1 | GHH-6 | GEH-5 | 4.11 | 115 | 116 |
| Example 55 | | | | | | |
| Present | GD-1 | GHH-6 | GEH-6 | 4.10 | 116 | 118 |
| Example 56 | | | | | | |
| Present | GD-1 | GHH-6 | GEH-7 | 4.14 | 112 | 110 |
| Example 57 | | | | | | |
| Present | GD-1 | GHH-6 | GEH-8 | 4.13 | 113 | 111 |
| Example 58 | | | | | | |
| Present | GD-1 | GHH-6 | GEH-9 | 4.18 | 108 | 113 |
| Example 59 | | | | | | |
| Present | GD-1 | GHH-6 | GEH-10 | 4.17 | 109 | 106 |
| Example 60 | | | | | | |

TABLE 5

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-7 | GEH-1 | 4.15 | 117 | 116 |
| Example 61 | | | | | | |
| Present | GD-1 | GHH-7 | GEH-2 | 4.14 | 116 | 114 |
| Example 62 | | | | | | |
| Present | GD-1 | GHH-7 | GEH-3 | 4.12 | 116 | 114 |
| Example 63 | | | | | | |
| Present | GD-1 | GHH-7 | GEH-4 | 4.14 | 113 | 112 |
| Example 64 | | | | | | |
| Present | GD-1 | GHH-7 | GEH-5 | 4.12 | 117 | 113 |
| Example 65 | | | | | | |
| Present | GD-1 | GHH-7 | GEH-6 | 4.13 | 114 | 112 |
| Example 66 | | | | | | |
| Present | GD-1 | GHH-7 | GEH-7 | 4.15 | 106 | 105 |
| Example 67 | | | | | | |
| Present | GD-1 | GHH-7 | GEH-8 | 4.17 | 112 | 107 |
| Example 68 | | | | | | |
| Present | GD-1 | GHH-7 | GEH-9 | 4.16 | 109 | 106 |
| Example 69 | | | | | | |
| Present | GD-1 | GHH-7 | GEH-10 | 4.19 | 102 | 101 |
| Example 70 | | | | | | |
| Present | GD-1 | GHH-8 | GEH-1 | 4.15 | 114 | 110 |
| Example 71 | | | | | | |
| Present | GD-1 | GHH-8 | GEH-2 | 4.14 | 116 | 112 |
| Example 72 | | | | | | |
| Present | GD-1 | GHH-8 | GEH-3 | 4.14 | 116 | 118 |
| Example 73 | | | | | | |
| Present | GD-1 | GHH-8 | GEH-4 | 4.14 | 112 | 110 |
| Example 74 | | | | | | |
| Present | GD-1 | GHH-8 | GEH-5 | 4.12 | 112 | 112 |
| Example 75 | | | | | | |

TABLE 6

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-8 | GEH-6 | 4.13 | 112 | 112 |
| Example 76 | | | | | | |
| Present | GD-1 | GHH-8 | GEH-7 | 4.19 | 106 | 102 |
| Example 77 | | | | | | |
| Present | GD-1 | GHH-8 | GEH-8 | 4.18 | 107 | 104 |
| Example 78 | | | | | | |
| Present | GD-1 | GHH-8 | GEH-9 | 4.17 | 109 | 106 |
| Example 79 | | | | | | |
| Present | GD-1 | GHH-8 | GEH-10 | 4.19 | 103 | 101 |
| Example 80 | | | | | | |
| Present | GD-1 | GHH-9 | GEH-1 | 4.11 | 117 | 113 |
| Example 81 | | | | | | |
| Present | GD-1 | GHH-9 | GEH-2 | 4.11 | 116 | 113 |
| Example 82 | | | | | | |
| Present | GD-1 | GHH-9 | GEH-3 | 4.11 | 115 | 113 |
| Example 83 | | | | | | |
| Present | GD-1 | GHH-9 | GEH-4 | 4.10 | 113 | 111 |
| Example 84 | | | | | | |
| Present | GD-1 | GHH-9 | GEH-5 | 4.09 | 115 | 113 |
| Example 85 | | | | | | |
| Present | GD-1 | GHH-9 | GEH-6 | 4.09 | 115 | 112 |
| Example 86 | | | | | | |
| Present | GD-1 | GHH-9 | GEH-7 | 4.14 | 104 | 101 |
| Example 87 | | | | | | |
| Present | GD-1 | GHH-9 | GEH-8 | 4.13 | 110 | 106 |
| Example 88 | | | | | | |
| Present | GD-1 | GHH-9 | GEH-9 | 4.13 | 109 | 106 |
| Example 89 | | | | | | |
| Present | GD-1 | GHH-9 | GEH-10 | 4.17 | 101 | 100 |
| Example 90 | | | | | | |

TABLE 7

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-1 | CBP | | 4.30 | 100 | 100 |
| Example 1 | | | | | | |
| Present | GD-1 | GHH-10 | GEH-1 | 4.13 | 114 | 111 |
| Example 91 | | | | | | |
| Present | GD-1 | GHH-10 | GEH-2 | 4.12 | 115 | 111 |
| Example 92 | | | | | | |
| Present | GD-1 | GHH-10 | GEH-3 | 4.14 | 111 | 110 |
| Example 93 | | | | | | |
| Present | GD-1 | GHH-10 | GEH-4 | 4.14 | 110 | 106 |
| Example 94 | | | | | | |
| Present | GD-1 | GHH-10 | GEH-5 | 4.14 | 110 | 108 |
| Example 95 | | | | | | |
| Present | GD-1 | GHH-10 | GEH-6 | 4.15 | 111 | 109 |
| Example 96 | | | | | | |
| Present | GD-1 | GHH-10 | GEH-7 | 4.18 | 104 | 100 |
| Example 97 | | | | | | |
| Present | GD-1 | GHH-10 | GEH-8 | 4.17 | 106 | 102 |
| Example 98 | | | | | | |
| Present | GD-1 | GHH-10 | GEH-9 | 4.20 | 105 | 104 |
| Example 99 | | | | | | |
| Present | GD-1 | GHH-10 | GEH-10 | 4.21 | 102 | 100 |

Example 100

TABLE 8

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-2 | CBP | | 4.31 | 100 | 100 |
| Example 2 | | | | | | |
| Present | GD-2 | GHH-1 | GEH-1 | 4.11 | 129 | 129 |
| Example 101 | | | | | | |
| Present | GD-2 | GHH-1 | GEH-2 | 4.09 | 132 | 128 |
| Example 102 | | | | | | |
| Present | GD-2 | GHH-1 | GEH-3 | 4.06 | 129 | 127 |
| Example 103 | | | | | | |
| Present | GD-2 | GHH-1 | GEH-4 | 4.08 | 124 | 126 |
| Example 104 | | | | | | |
| Present | GD-2 | GHH-1 | GEH-5 | 4.06 | 127 | 124 |
| Example 105 | | | | | | |
| Present | GD-2 | GHH-2 | GEH-1 | 4.09 | 130 | 126 |
| Example 106 | | | | | | |
| Present | GD-2 | GHH-2 | GEH-2 | 4.08 | 135 | 129 |
| Example 107 | | | | | | |
| Present | GD-2 | GHH-2 | GEH-3 | 4.04 | 140 | 144 |
| Example 108 | | | | | | |
| Present | GD-2 | GHH-2 | GEH-4 | 4.05 | 133 | 133 |
| Example 109 | | | | | | |
| Present | GD-2 | GHH-2 | GEH-5 | 4.03 | 132 | 135 |
| Example 110 | | | | | | |
| Present | GD-2 | GHH-3 | GEH-1 | 4.05 | 135 | 132 |
| Example 111 | | | | | | |
| Present | GD-2 | GHH-3 | GEH-2 | 4.06 | 130 | 127 |
| Example 112 | | | | | | |
| Present | GD-2 | GHH-3 | GEH-3 | 4.05 | 132 | 129 |
| Example 113 | | | | | | |
| Present | GD-2 | GHH-3 | GEH-4 | 4.06 | 131 | 126 |
| Example 114 | | | | | | |
| Present | GD-2 | GHH-3 | GEH-5 | 4.05 | 135 | 129 |
| Example 115 | | | | | | |

TABLE 9

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-2 | CBP | | 4.31 | 100 | 100 |
| Example 2 | | | | | | |
| Present | GD-2 | GHH-4 | GEH-1 | 4.07 | 129 | 125 |
| Example 116 | | | | | | |
| Present | GD-2 | GHH-4 | GEH-2 | 4.06 | 130 | 126 |
| Example 117 | | | | | | |
| Present | GD-2 | GHH-4 | GEH-3 | 4.09 | 123 | 124 |
| Example 118 | | | | | | |
| Present | GD-2 | GHH-4 | GEH-4 | 4.08 | 121 | 118 |
| Example 119 | | | | | | |
| Present | GD-2 | GHH-4 | GEH-5 | 4.07 | 123 | 121 |
| Example 120 | | | | | | |
| Present | GD-2 | GHH-5 | GEH-1 | 4.05 | 127 | 122 |
| Example 121 | | | | | | |
| Present | GD-2 | GHH-5 | GEH-2 | 4.03 | 130 | 126 |
| Example 122 | | | | | | |
| Present | GD-2 | GHH-5 | GEH-3 | 4.04 | 125 | 124 |
| Example 123 | | | | | | |
| Present | GD-2 | GHH-5 | GEH-4 | 4.02 | 122 | 123 |
| Example 124 | | | | | | |
| Present | GD-2 | GHH-5 | GEH-5 | 4.01 | 123 | 124 |
| Example 125 | | | | | | |

TABLE 10

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-3 | CBP | | 4.32 | 100 | 100 |
| Example 3 | | | | | | |
| Present | GD-3 | GHH-1 | GEH-1 | 4.13 | 124 | 125 |
| Example 126 | | | | | | |
| Present | GD-3 | GHH-1 | GEH-2 | 4.11 | 127 | 124 |
| Example 127 | | | | | | |
| Present | GD-3 | GHH-1 | GEH-3 | 4.08 | 124 | 123 |
| Example 128 | | | | | | |
| Present | GD-3 | GHH-1 | GEH-4 | 4.10 | 120 | 122 |
| Example 129 | | | | | | |
| Present | GD-3 | GHH-1 | GEH-5 | 4.08 | 123 | 120 |
| Example 130 | | | | | | |
| Present | GD-3 | GHH-2 | GEH-1 | 4.11 | 125 | 122 |
| Example 131 | | | | | | |
| Present | GD-3 | GHH-2 | GEH-2 | 4.10 | 130 | 125 |
| Example 132 | | | | | | |
| Present | GD-3 | GHH-2 | GEH-3 | 4.06 | 135 | 140 |
| Example 133 | | | | | | |
| Present | GD-3 | GHH-2 | GEH-4 | 4.07 | 128 | 128 |
| Example 134 | | | | | | |
| Present | GD-3 | GHH-2 | GEH-5 | 4.05 | 127 | 130 |
| Example 135 | | | | | | |
| Present | GD-3 | GHH-3 | GEH-1 | 4.07 | 130 | 127 |
| Example 136 | | | | | | |
| Present | GD-3 | GHH-3 | GEH-2 | 4.08 | 125 | 123 |
| Example 137 | | | | | | |
| Present | GD-3 | GHH-3 | GEH-3 | 4.07 | 127 | 125 |
| Example 138 | | | | | | |
| Present | GD-3 | GHH-3 | GEH-4 | 4.08 | 126 | 122 |
| Example 139 | | | | | | |
| Present | GD-3 | GHH-3 | GEH-5 | 4.07 | 130 | 125 |
| Example 140 | | | | | | |

TABLE 11

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-3 | CBP | | 4.32 | 100 | 100 |
| Example 3 | | | | | | |
| Present | GD-3 | GHH-4 | GEH-1 | 4.09 | 124 | 121 |
| Example 141 | | | | | | |
| Present | GD-3 | GHH-4 | GEH-2 | 4.08 | 125 | 122 |
| Example 142 | | | | | | |
| Present | GD-3 | GHH-4 | GEH-3 | 4.11 | 119 | 120 |
| Example 143 | | | | | | |
| Present | GD-3 | GHH-4 | GEH-4 | 4.10 | 116 | 114 |
| Example 144 | | | | | | |
| Present | GD-3 | GHH-4 | GEH-5 | 4.09 | 119 | 117 |
| Example 145 | | | | | | |
| Present | GD-3 | GHH-5 | GEH-1 | 4.07 | 123 | 118 |
| Example 146 | | | | | | |
| Present | GD-3 | GHH-5 | GEH-2 | 4.05 | 125 | 122 |
| Example 147 | | | | | | |
| Present | GD-3 | GHH-5 | GEH-3 | 4.06 | 121 | 120 |
| Example 148 | | | | | | |
| Present | GD-3 | GHH-5 | GEH-4 | 4.04 | 118 | 119 |
| Example 149 | | | | | | |
| Present | GD-3 | GHH-5 | GEH-5 | 4.03 | 119 | 120 |
| Example 150 | | | | | | |

TABLE 12

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-4 | CBP | | 4.32 | 100 | 100 |
| Example 4 | | | | | | |
| Present | GD-4 | GHH-1 | GEH-1 | 4.14 | 121 | 123 |
| Example 151 | | | | | | |
| Present | GD-4 | GHH-1 | GEH-2 | 4.12 | 124 | 122 |
| Example 152 | | | | | | |
| Present | GD-4 | GHH-1 | GEH-3 | 4.09 | 121 | 121 |
| Example 153 | | | | | | |
| Present | GD-4 | GHH-1 | GEH-4 | 4.11 | 117 | 120 |
| Example 154 | | | | | | |
| Present | GD-4 | GHH-1 | GEH-5 | 4.09 | 120 | 118 |
| Example 155 | | | | | | |
| Present | GD-4 | GHH-2 | GEH-1 | 4.12 | 122 | 120 |
| Example 156 | | | | | | |
| Present | GD-4 | GHH-2 | GEH-2 | 4.11 | 128 | 123 |
| Example 157 | | | | | | |
| Present | GD-4 | GHH-2 | GEH-3 | 4.07 | 133 | 137 |
| Example 158 | | | | | | |
| Present | GD-4 | GHH-2 | GEH-4 | 4.08 | 125 | 126 |
| Example 159 | | | | | | |
| Present | GD-4 | GHH-2 | GEH-5 | 4.06 | 124 | 128 |
| Example 160 | | | | | | |
| Present | GD-4 | GHH-3 | GEH-1 | 4.08 | 128 | 125 |
| Example 161 | | | | | | |
| Present | GD-4 | GHH-3 | GEH-2 | 4.09 | 122 | 121 |
| Example 162 | | | | | | |
| Present | GD-4 | GHH-3 | GEH-3 | 4.08 | 124 | 123 |
| Example 163 | | | | | | |
| Present | GD-4 | GHH-3 | GEH-4 | 4.09 | 123 | 120 |
| Example 164 | | | | | | |
| Present | GD-4 | GHH-3 | GEH-5 | 4.08 | 128 | 123 |
| Example 165 | | | | | | |

TABLE 13

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-4 | CBP | | 4.32 | 100 | 100 |
| Example 4 | | | | | | |
| Present | GD-4 | GHH-4 | GEH-1 | 4.10 | 121 | 119 |
| Example 166 | | | | | | |
| Present | GD-4 | GHH-4 | GEH-2 | 4.09 | 122 | 120 |
| Example 167 | | | | | | |
| Present | GD-4 | GHH-4 | GEH-3 | 4.12 | 116 | 118 |
| Example 168 | | | | | | |
| Present | GD-4 | GHH-4 | GEH-4 | 4.11 | 114 | 112 |
| Example 169 | | | | | | |
| Present | GD-4 | GHH-4 | GEH-5 | 4.10 | 116 | 115 |
| Example 170 | | | | | | |
| Present | GD-4 | GHH-5 | GEH-1 | 4.08 | 120 | 116 |
| Example 171 | | | | | | |
| Present | GD-4 | GHH-5 | GEH-2 | 4.06 | 122 | 120 |
| Example 172 | | | | | | |
| Present | GD-4 | GHH-5 | GEH-3 | 4.07 | 118 | 118 |
| Example 173 | | | | | | |
| Present | GD-4 | GHH-5 | GEH-4 | 4.05 | 115 | 117 |
| Example 174 | | | | | | |
| Present | GD-4 | GHH-5 | GEH-5 | 4.04 | 116 | 118 |
| Example 175 | | | | | | |

TABLE 14

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-5 | CBP | | 4.32 | 100 | 100 |
| Example 5 | | | | | | |
| Present | GD-5 | GHH-1 | GEH-1 | 4.12 | 125 | 126 |
| Example 176 | | | | | | |
| Present | GD-5 | GHH-1 | GEH-2 | 4.10 | 128 | 125 |
| Example 177 | | | | | | |
| Present | GD-5 | GHH-1 | GEH-3 | 4.07 | 125 | 124 |
| Example 178 | | | | | | |
| Present | GD-5 | GHH-1 | GEH-4 | 4.09 | 121 | 123 |
| Example 179 | | | | | | |
| Present | GD-5 | GHH-1 | GEH-5 | 4.07 | 124 | 121 |
| Example 180 | | | | | | |
| Present | GD-5 | GHH-2 | GEH-1 | 4.10 | 126 | 123 |
| Example 181 | | | | | | |
| Present | GD-5 | GHH-2 | GEH-2 | 4.09 | 131 | 126 |
| Example 182 | | | | | | |
| Present | GD-5 | GHH-2 | GEH-3 | 4.05 | 137 | 141 |
| Example 183 | | | | | | |
| Present | GD-5 | GHH-2 | GEH-4 | 4.06 | 129 | 129 |
| Example 184 | | | | | | |
| Present | GD-5 | GHH-2 | GEH-5 | 4.04 | 128 | 132 |
| Example 185 | | | | | | |
| Present | GD-5 | GHH-3 | GEH-1 | 4.06 | 131 | 128 |
| Example 186 | | | | | | |
| Present | GD-5 | GHH-3 | GEH-2 | 4.07 | 126 | 124 |
| Example 187 | | | | | | |
| Present | GD-5 | GHH-3 | GEH-3 | 4.06 | 128 | 126 |
| Example 188 | | | | | | |
| Present | GD-5 | GHH-3 | GEH-4 | 4.07 | 127 | 123 |
| Example 189 | | | | | | |
| Present | GD-5 | GHH-3 | GEH-5 | 4.06 | 131 | 126 |
| Example 190 | | | | | | |

TABLE 15

| | | | | Operation | EQE | LT95 |
|---|---|---|---|---|---|---|
| | Light-emissive layer | | | voltage | (%, relative | (%, relative |
| | Dopant | Host | | (V) | value) | value) |
| Comparative | GD-5 | CBP | | 4.32 | 100 | 100 |
| Example 5 | | | | | | |
| Present | GD-5 | GHH-4 | GEH-1 | 4.08 | 125 | 122 |
| Example 191 | | | | | | |
| Present | GD-5 | GHH-4 | GEH-2 | 4.07 | 126 | 123 |
| Example 192 | | | | | | |
| Present | GD-5 | GHH-4 | GEH-3 | 4.10 | 120 | 121 |
| Example 193 | | | | | | |
| Present | GD-5 | GHH-4 | GEH-4 | 4.09 | 118 | 115 |
| Example 194 | | | | | | |
| Present | GD-5 | GHH-4 | GEH-5 | 4.08 | 120 | 118 |
| Example 195 | | | | | | |
| Present | GD-5 | GHH-5 | GEH-1 | 4.06 | 124 | 119 |
| Example 196 | | | | | | |
| Present | GD-5 | GHH-5 | GEH-2 | 4.04 | 126 | 123 |
| Example 197 | | | | | | |
| Present | GD-5 | GHH-5 | GEH-3 | 4.05 | 122 | 121 |
| Example 198 | | | | | | |
| Present | GD-5 | GHH-5 | GEH-4 | 4.03 | 119 | 120 |
| Example 199 | | | | | | |
| Present | GD-5 | GHH-5 | GEH-5 | 4.02 | 120 | 121 |
| Example 200 | | | | | | |

It may be identified from the results of Table 1 to Table 15 that the organic light-emitting diode of each of Present Examples 1 to 200 in which the organometallic compound satisfying the structure represented by Chemical Formula 1 of the present disclosure is used as the dopant of the light-emissive layer, and a mixture of the compound represented by Chemical Formula 2 and the compound represented by Chemical Formula 3 is used as the host of the light-emissive layer has lowered operation voltage, and improved external quantum efficiency (EQE) and lifetime (LT95), compared to the organic light-emitting diode of each of Comparative Examples 1 to 5 in which a single material is used as the host of the light-emissive layer.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. An organic light-emitting device comprising:
a first electrode;
a second electrode facing the first electrode; and
an organic layer disposed between the first electrode and the second electrode;
wherein the organic layer includes a light-emissive layer,
wherein the light-emissive layer includes a dopant material and a host material,
wherein the dopant material includes an organometallic compound represented by Chemical Formula 1,
wherein the host material includes a mixture of a compound represented by Chemical Formula 2 and a compound represented by Chemical Formula 3: 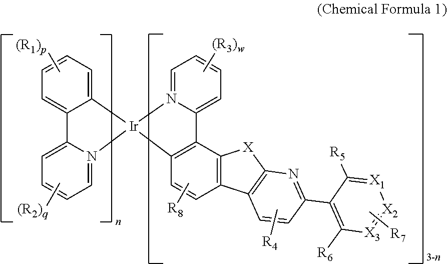
wherein in Chemical Formula 1,
X represents one chosen from oxygen (O), sulfur (S) and selenium (Se),
each of X₁, X₂ and X₃ independently represents nitrogen (N) or CR′,
each of R₁, R₂, R₃, R₄, R₇, R₈ and R′ independently represents one chosen from hydrogen, deuterium, halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₁, R₂, R₃, R₄, R₇, R₈ and R′ is unsubstituted or substituted with deuterium,
wherein each of R₅ and R₆ independently represents one chosen from halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₅ and R₆ is unsubstituted or substituted with deuterium,
n is an integer from 0 to 2, 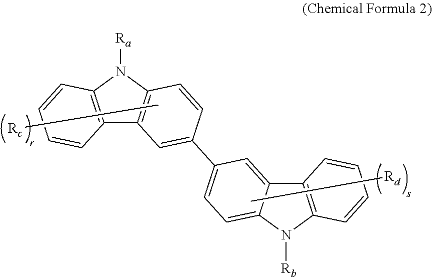
wherein in Chemical Formula 2,
each of Rₐ and R_{b} represents one chosen from a C3-C40 monocyclic aryl group, a polycyclic aryl group, a monocyclic heteroaryl group, and a polycyclic heteroaryl group, wherein each of Rₐ and R_{b} independently is unsubstituted or substituted with at least one substituent chosen from an alkyl group, an aryl group, a heteroaryl group, a cyano group, an alkylsilyl group, and an arylsilyl group,
each of R_{c} and R_{d} represents one chosen from hydrogen, deuterium, halogen, a cyano group and an alkyl group, wherein each of r and s independently represents an integer from 0 to 7, wherein when r is 2 or more, each R_{c} in (R_{c})ᵣ is the same as or different from each other, and wherein when s is 2 or more, each R_{d} in (R_{d})ₛ is the same as or different from each other, 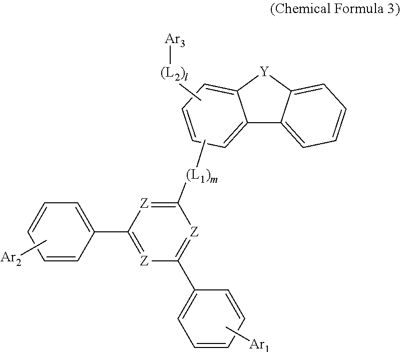
wherein in Chemical Formula 3,
each of Z_{S} independently represents nitrogen (N) or CR⁰, wherein at least two of Z_{S} are nitrogen (N),
R⁰ represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Y represents either oxygen (O) or sulfur (S),
each of L₁ and L₂ independently represents one chosen from a single bond, hydrogen, deuterium, halogen, halide, an amino group, a nitrile group, a nitro group, an alkyl group, an alkenyl group, an alkynyl group, an alkoxy group, an aryloxy group and an arylene group,
each of l and m independently represents an integer from 0 to 2,
each of Ar₁ and Ar₂ independently represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Ar₃ represents a C6-C60 aryl group.

2. The organic light-emitting device of claim 1, wherein in Chemical Formula 1, n is 2.

3. The organic light-emitting device of claim 1, wherein X in Chemical Formula 1 is oxygen (O).

4. The organic light-emitting device of claim 1, wherein the organometallic compound represented by Chemical Formula 1 is one chosen from compound GD-1 to compound GD-10:

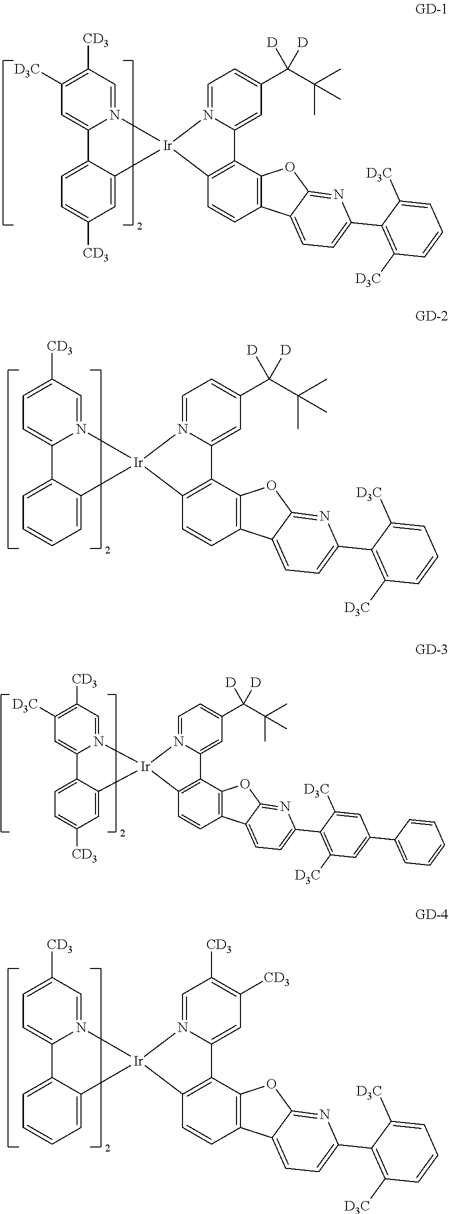

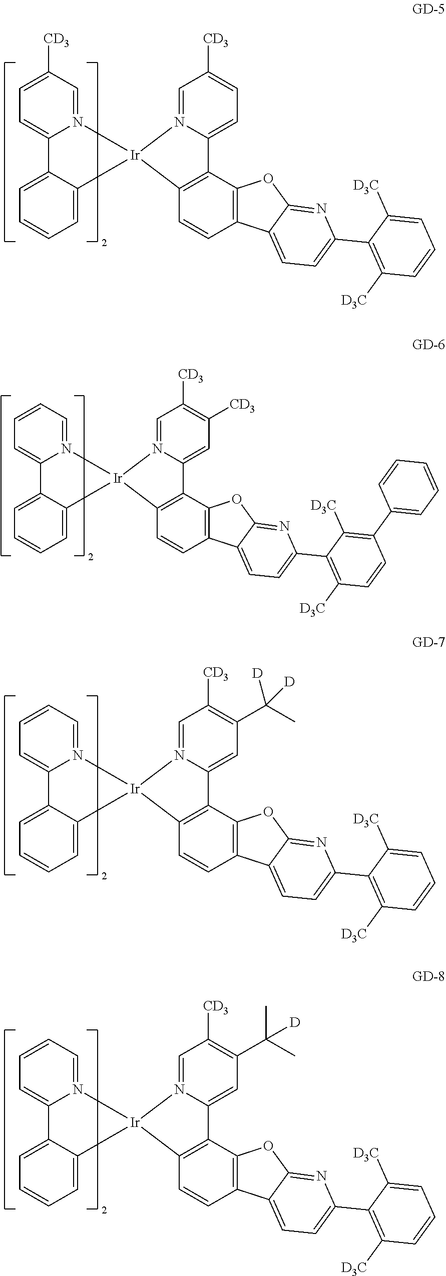

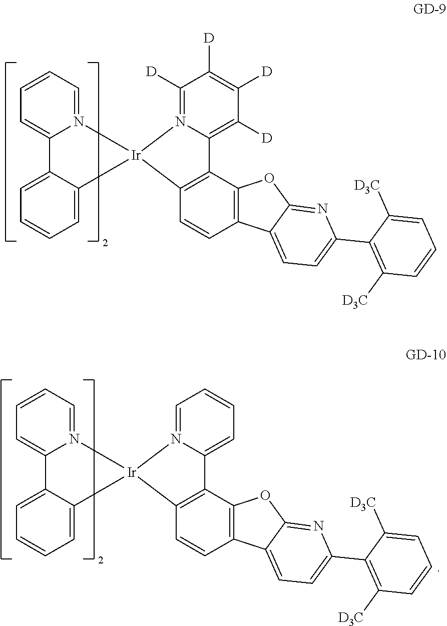

5. The organic light-emitting device of claim 1, wherein each of Rₐ and R_{b} of Chemical Formula 2 independently represents one chosen from a phenyl group, a naphthyl group, an anthracene group, a chrysene group, a pyrene group, a phenanthrene group, a triphenylene group, a fluorene group, and a 9,9′-spirofluorene group.

6. The organic light-emitting device of claim 1, wherein the compound represented by Chemical Formula 2 is one chosen from compound GHH-1 to compound GHH-20:

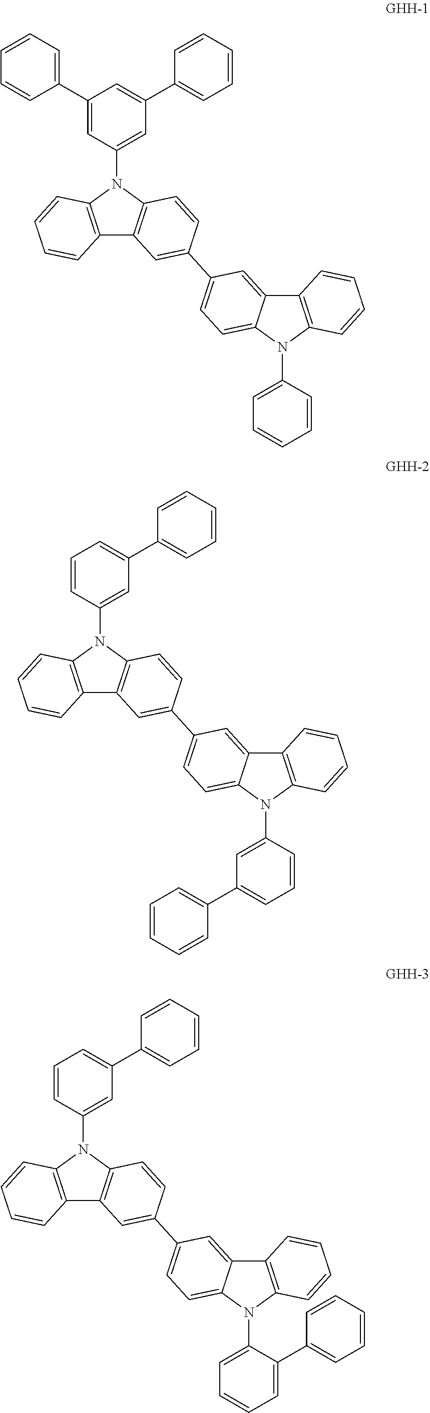

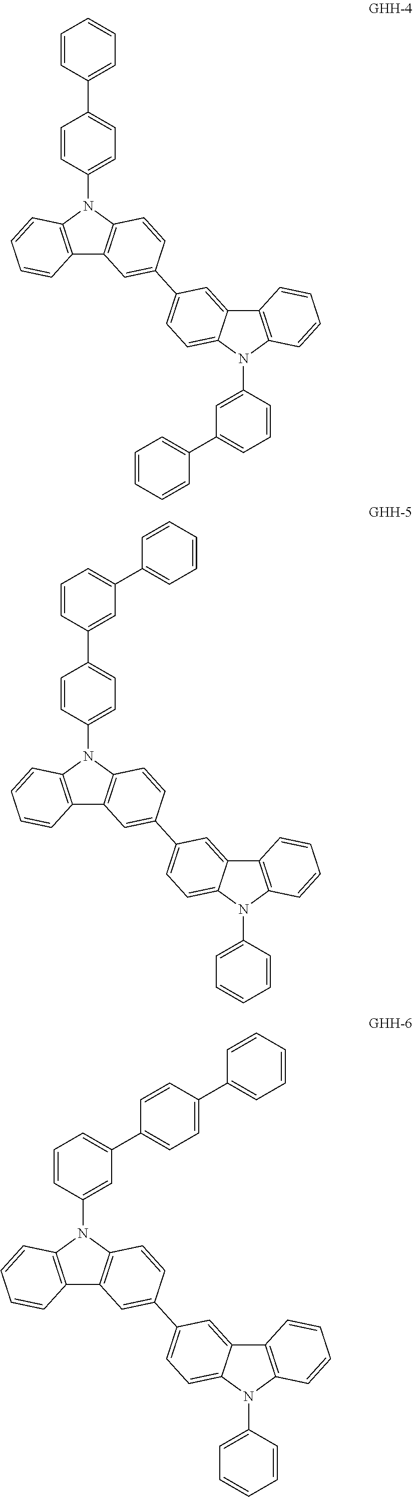

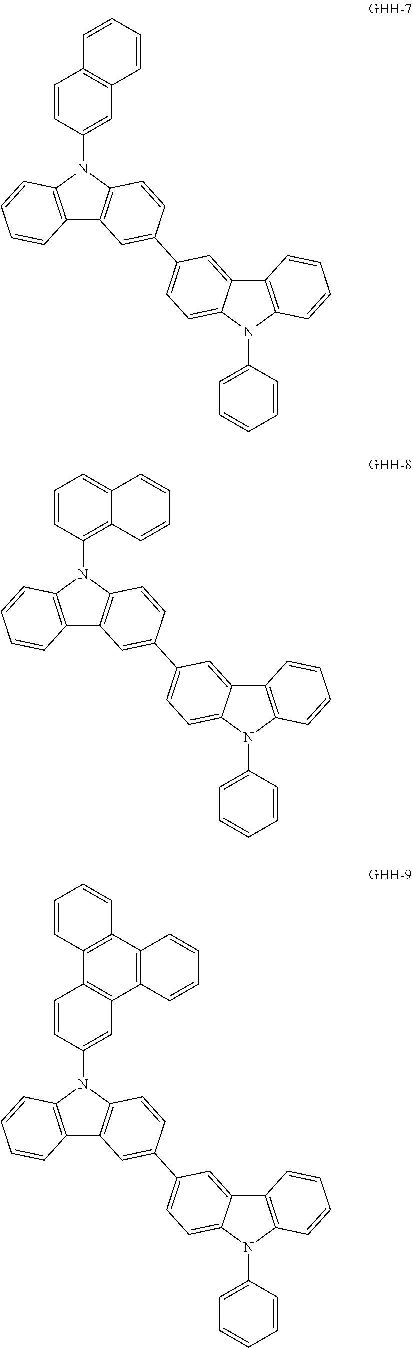 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

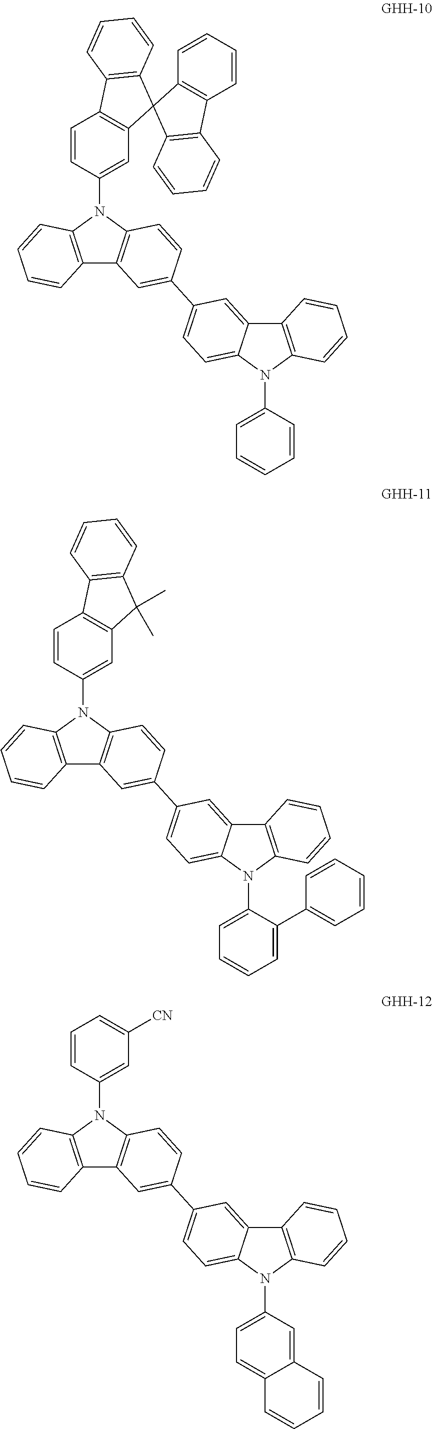 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

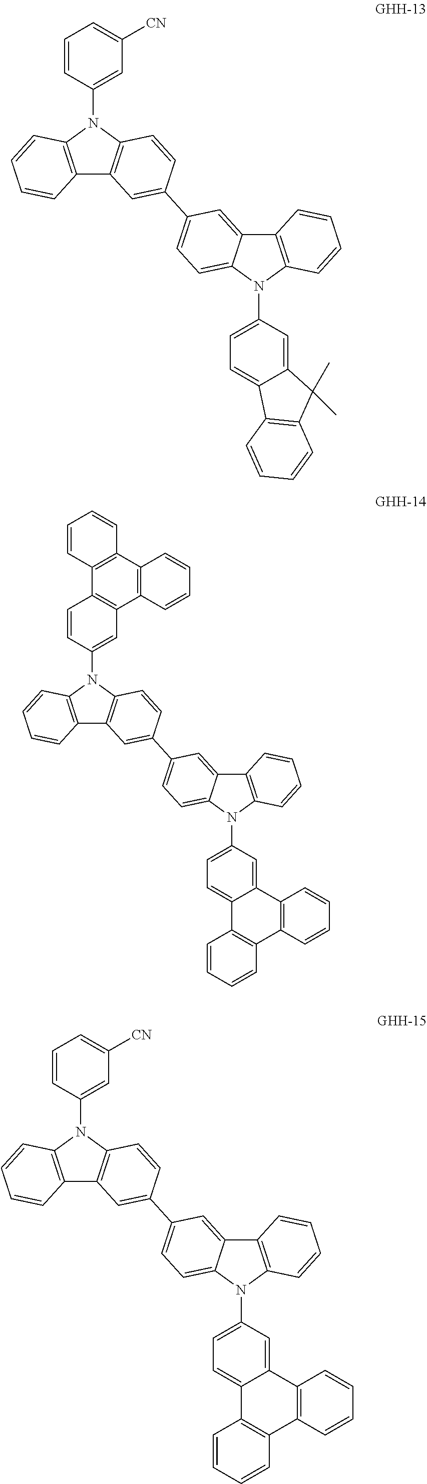 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

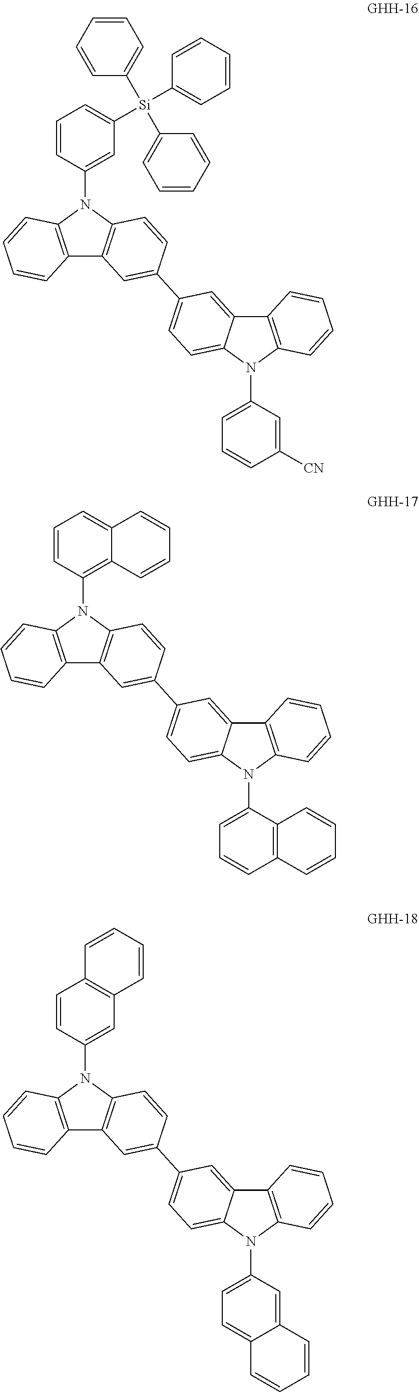 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

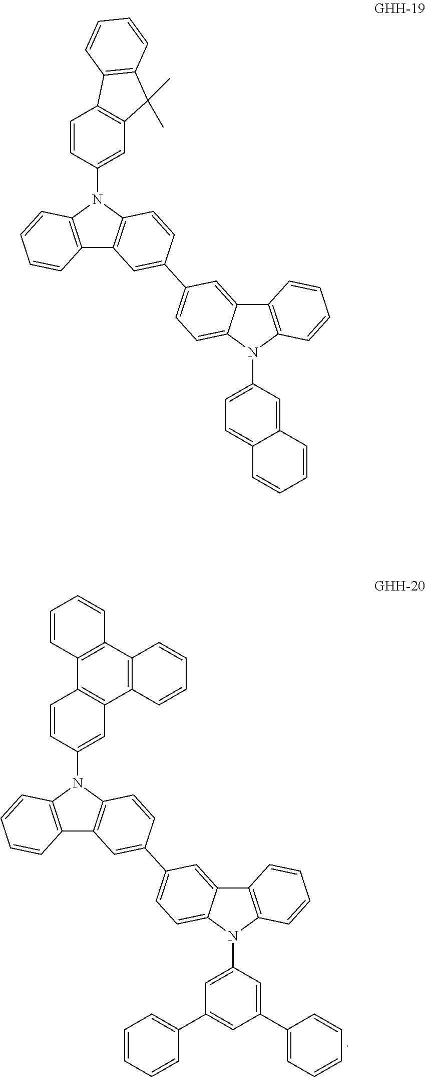 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1]

7. The organic light-emitting device of claim 1, wherein each of l and m of Chemical Formula 3 independently represents 0 or 1.

8. The organic light-emitting device of claim 1, wherein each of Ar₁ and Ar₂ of Chemical Formula 3 independently represents hydrogen or a C6-C50 aryl group.

9. The organic light-emitting device of claim 1, wherein Ar₃ of Chemical Formula 3 is one chosen from a phenyl group, a biphenyl group, a terphenyl group, a naphthyl group, an anthracenyl group, a phenanthryl group, a pyrenyl group, a perylenyl group, a chrysenyl group, and a substituted or unsubstituted fluorenyl group.

10. The organic light-emitting device of claim 1, wherein the compound represented by Chemical Formula 3 is one chosen from compound GEH-1 to compound GEH-20:

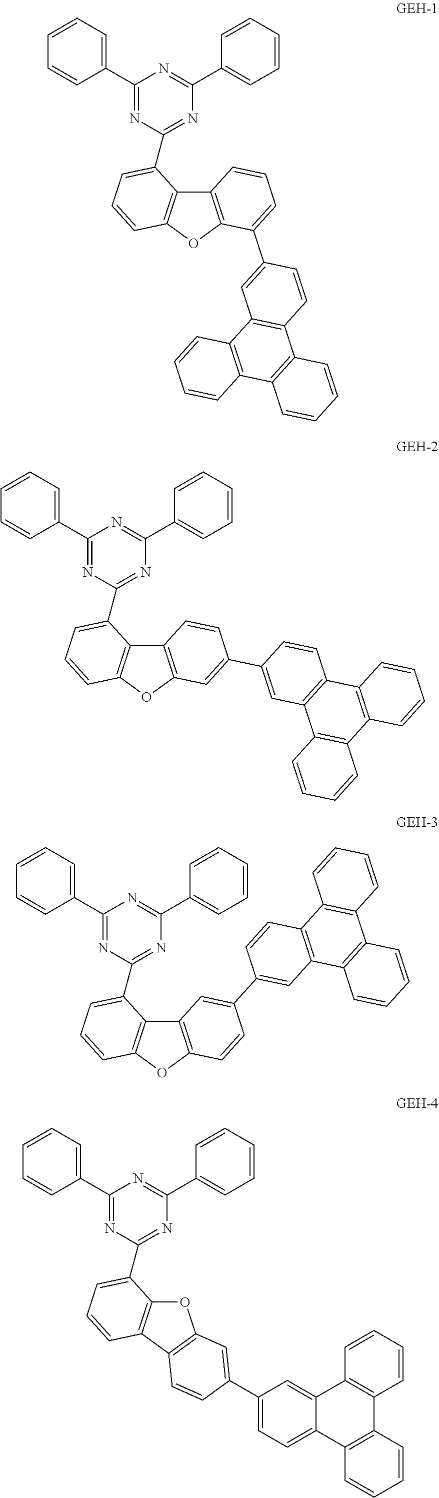 [SMILES: c1ccc(-c2nc(-c3ccccc3)nc(-c3cccc4oc5c(-c6ccc7c8ccccc8c8ccccc8c7c6)cccc5c34)n2)cc1 ; c1ccc(-c2nc(-c3ccccc3)nc(-c3cccc4oc5cc(-c6ccc7c8ccccc8c8ccccc8c7c6)ccc5c34)n2)cc1 ; c1ccc(-c2nc(-c3ccccc3)nc(-c3cccc4oc5ccc(-c6ccc7c8ccccc8c8ccccc8c7c6)cc5c34)n2)cc1 ; c1ccc(-c2nc(-c3ccccc3)nc(-c3cccc4c3oc3cc(-c5ccc6c7ccccc7c7ccccc7c6c5)ccc34)n2)cc1]

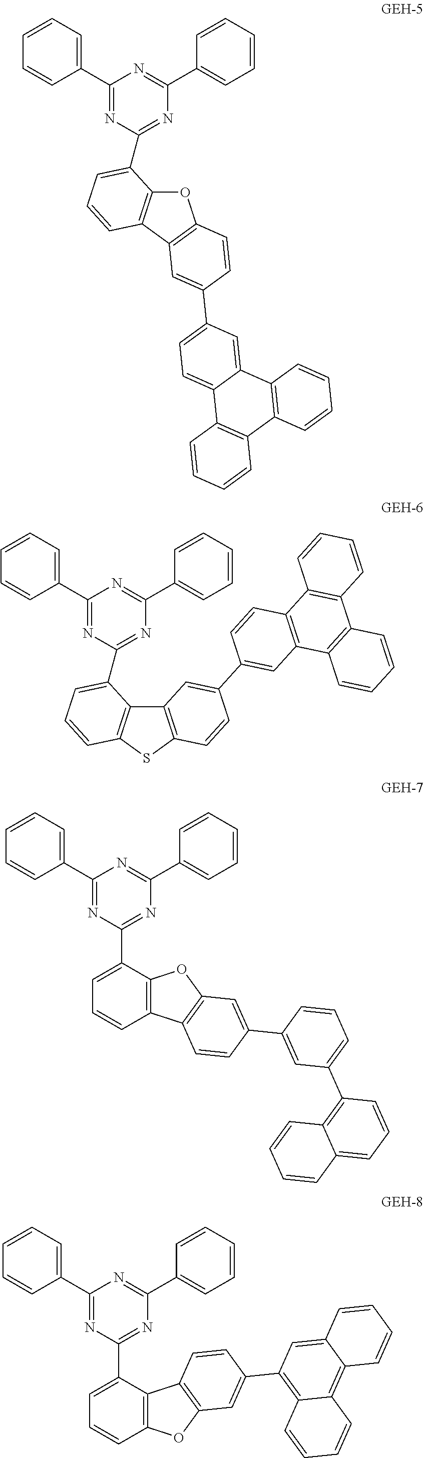 [SMILES: c1ccc(-c2nc(-c3ccccc3)nc(-c3cccc4c3oc3ccc(-c5ccc6c7ccccc7c7ccccc7c6c5)cc34)n2)cc1 ; c1ccc(-c2nc(-c3ccccc3)nc(-c3cccc4sc5ccc(-c6ccc7c8ccccc8c8ccccc8c7c6)cc5c34)n2)cc1 ; c1ccc(-c2nc(-c3ccccc3)nc(-c3cccc4c3oc3cc(-c5cccc(-c6cccc7ccccc67)c5)ccc34)n2)cc1 ; c1ccc(-c2nc(-c3ccccc3)nc(-c3cccc4oc5cc(-c6cc7ccccc7c7ccccc67)ccc5c34)n2)cc1]

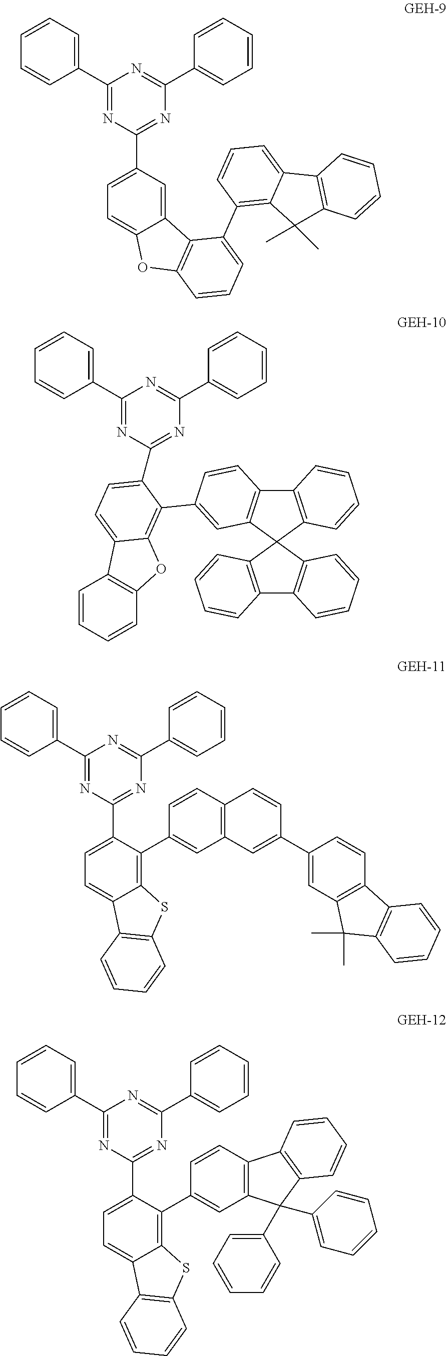

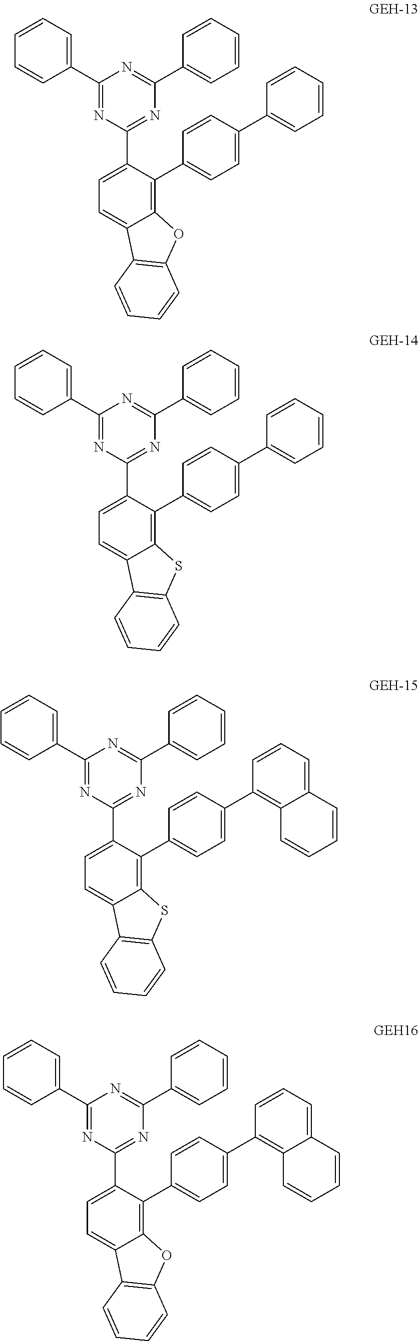 [SMILES: c1ccc(-c2ccc(-c3c(-c4nc(-c5ccccc5)nc(-c5ccccc5)n4)ccc4c3oc3ccccc34)cc2)cc1 ; c1ccc(-c2ccc(-c3c(-c4nc(-c5ccccc5)nc(-c5ccccc5)n4)ccc4c3sc3ccccc34)cc2)cc1 ; c1ccc(-c2nc(-c3ccccc3)nc(-c3ccc4c(sc5ccccc54)c3-c3ccc(-c4cccc5ccccc45)cc3)n2)cc1 ; c1ccc(-c2nc(-c3ccccc3)nc(-c3ccc4c(oc5ccccc54)c3-c3ccc(-c4cccc5ccccc45)cc3)n2)cc1]

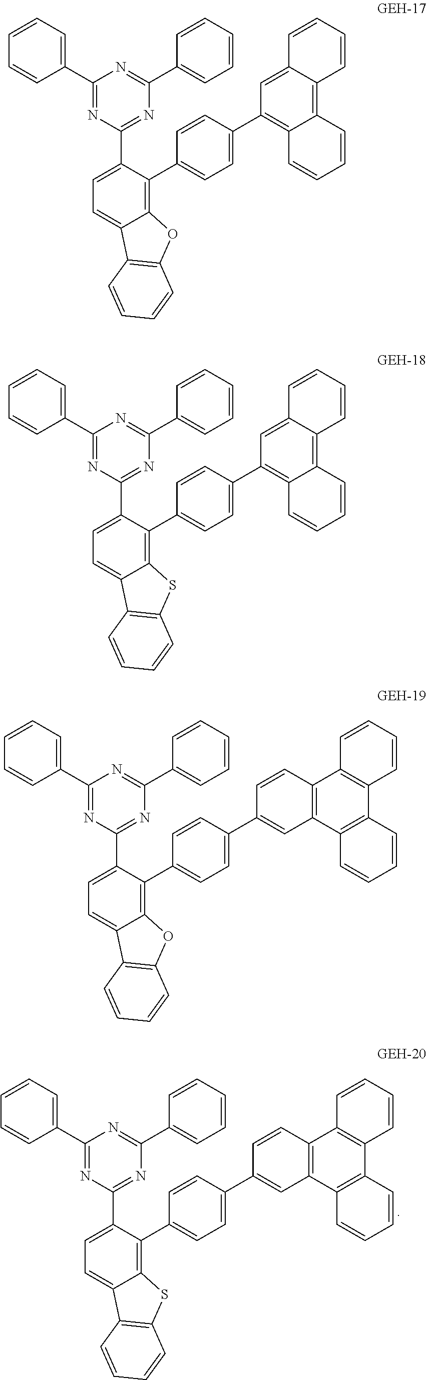 [SMILES: c1ccc(-c2nc(-c3ccccc3)nc(-c3ccc4c(oc5ccccc54)c3-c3ccc(-c4cc5ccccc5c5ccccc45)cc3)n2)cc1 ; c1ccc(-c2nc(-c3ccccc3)nc(-c3ccc4c(sc5ccccc54)c3-c3ccc(-c4cc5ccccc5c5ccccc45)cc3)n2)cc1 ; c1ccc(-c2nc(-c3ccccc3)nc(-c3ccc4c(oc5ccccc54)c3-c3ccc(-c4ccc5c6ccccc6c6ccccc6c5c4)cc3)n2)cc1 ; c1ccc(-c2nc(-c3ccccc3)nc(-c3ccc4c(sc5ccccc54)c3-c3ccc(-c4ccc5c6ccccc6c6ccccc6c5c4)cc3)n2)cc1]

11. The organic light-emitting device of claim 1, wherein the organic layer further includes at least one chosen from a hole injection layer, a hole transport layer, an electron transport layer, and an electron injection layer.

12. An organic light-emitting device comprising:
a first electrode;
a second electrode facing the first electrode; and
a first light-emitting stack and a second light-emitting stack disposed between the first electrode and the second electrode,
wherein each of the first light-emitting stack and the second light-emitting stack includes at least one light-emissive layer,
wherein the at least one light-emissive layer comprises a green phosphorescent light-emissive layer,
wherein the green phosphorescent light-emissive layer includes a dopant material and a host material,
wherein the dopant material includes an organometallic compound represented by Chemical Formula 1,
wherein the host material includes a mixture of a compound represented by Chemical Formula 2 and a compound represented by Chemical Formula 3: 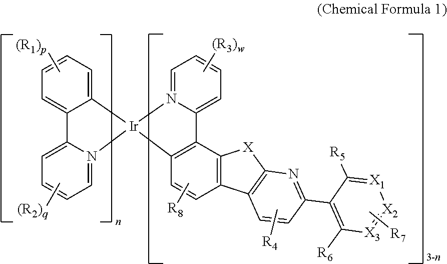
wherein in Chemical Formula 1,
X represents one chosen from oxygen (O), sulfur (S) and selenium (Se),
each of X₁, X₂ and X₃ independently represents nitrogen (N) or CR′,
each of R₁, R₂, R₃, R₄, R₇, R₈ and R′ independently represents one chosen from hydrogen, deuterium, halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₁, R₂, R₃, R₄, R₇, R₈ and R′is unsubstituted or substituted with deuterium,
wherein each of R₅ and R₆ independently represents one chosen from halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₅ and R₆ is unsubstituted or substituted with deuterium,
n is an integer from 0 to 2, 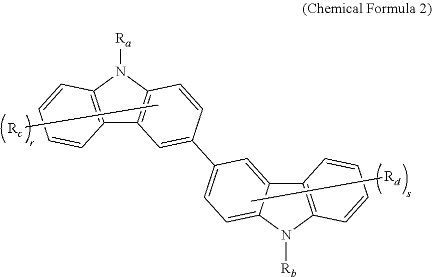
wherein in Chemical Formula 2,
each of Rₐ and R_{b} represents one chosen from a C3-C40 monocyclic aryl group, a polycyclic aryl group, a monocyclic heteroaryl group, and a polycyclic heteroaryl group, wherein each of Rₐ and R_{b} independently is unsubstituted or substituted with at least one substituent selected from a group consisting of an alkyl group, an aryl group, a heteroaryl group, a cyano group, an alkylsilyl group, and an arylsilyl group,
each of R_{c} and R_{d} represents one selected from a group consisting of hydrogen, deuterium, halogen, a cyano group and an alkyl group, wherein each of r and s independently represents an integer from 0 to 7, wherein when r is 2 or more, each R_{c} in (R_{c})ᵣ is the same as or different from each other, and wherein when s is 2 or more, each R_{d} in (R_{d})ₛ is the same as or different from each other, 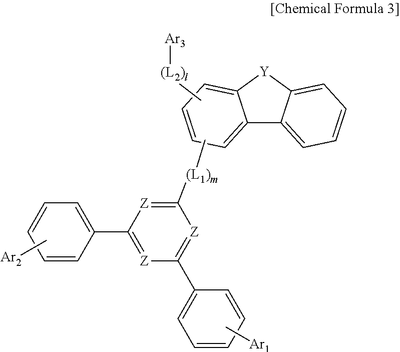
wherein in Chemical Formula 3,
each of Z_{S} independently represents nitrogen (N) or CR⁰, wherein at least two of Z_{S} are nitrogen (N),
R₀ represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Y represents either oxygen (O) or sulfur (S),
each of L₁ and L₂ independently represents one chosen from a single bond, an amino group, a nitrile group, a nitro group, an alkylene group, an alkenylene group, an alkynylene group, an oxyalkylene group, an oxyarylene group and an arylene group,
each of l and m independently represents an integer from 0 to 2,
each of Ar₁ and Ar₂ independently represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Ar₃ represents a C6-C60 aryl group.

13. The organic light-emitting device of claim 12, wherein the organometallic compound represented by Chemical Formula 1 comprises one chosen from compound GD-1 to compound GD-10:

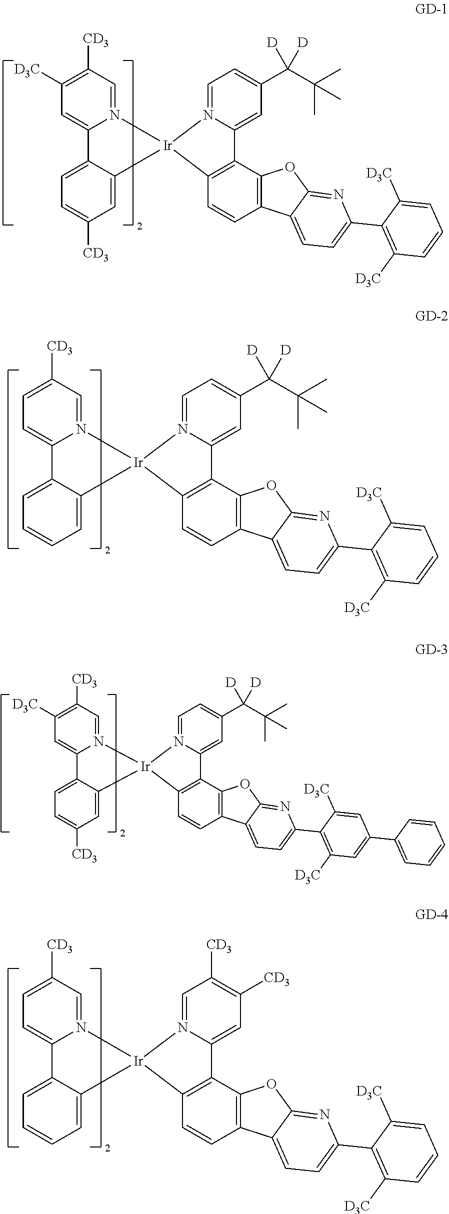

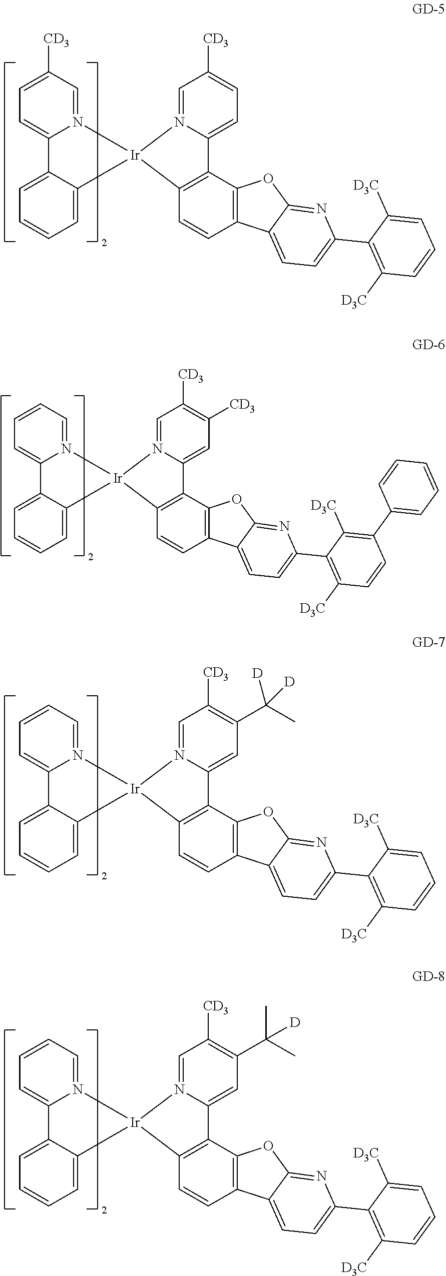

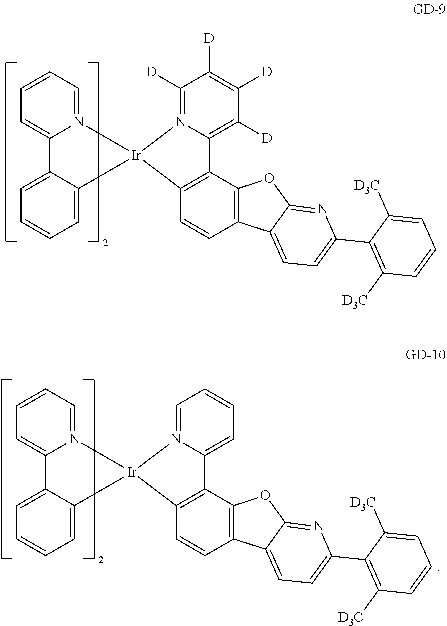

14. The organic light-emitting device of claim 12, wherein the compound represented by Chemical Formula 2 comprises one chosen from compound GHH-1 to compound GHH-20:

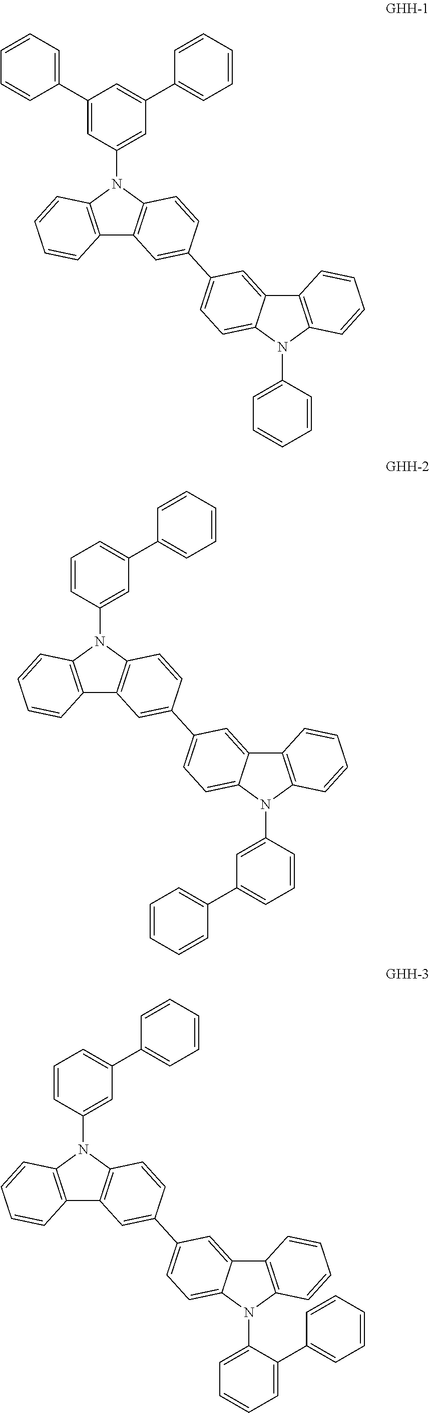

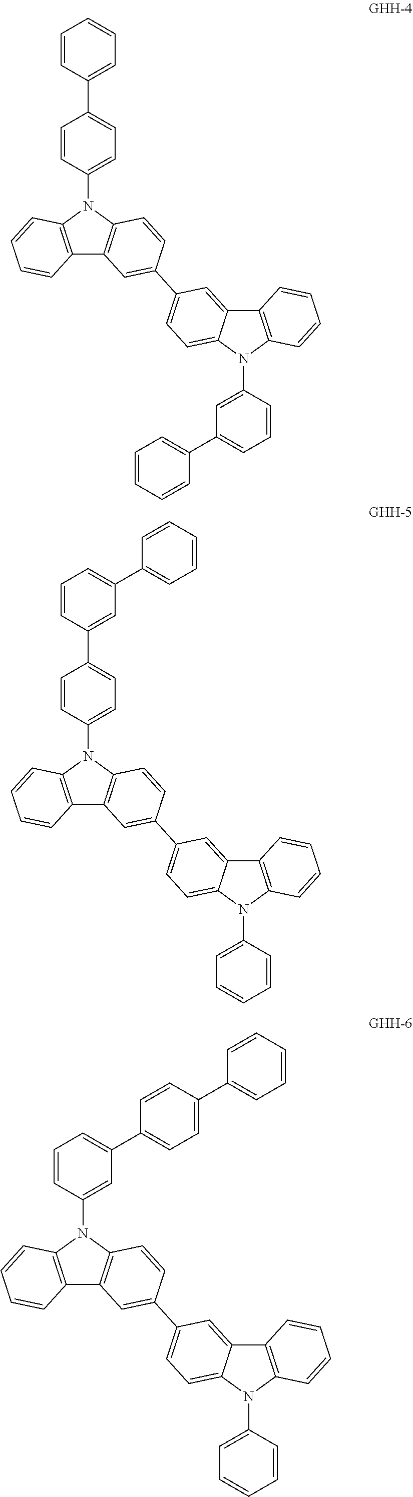

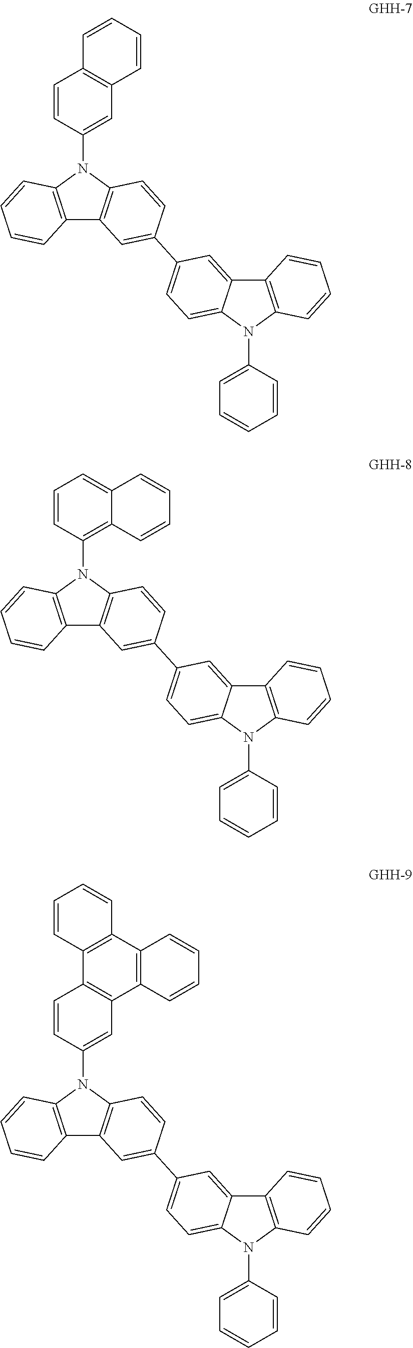 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

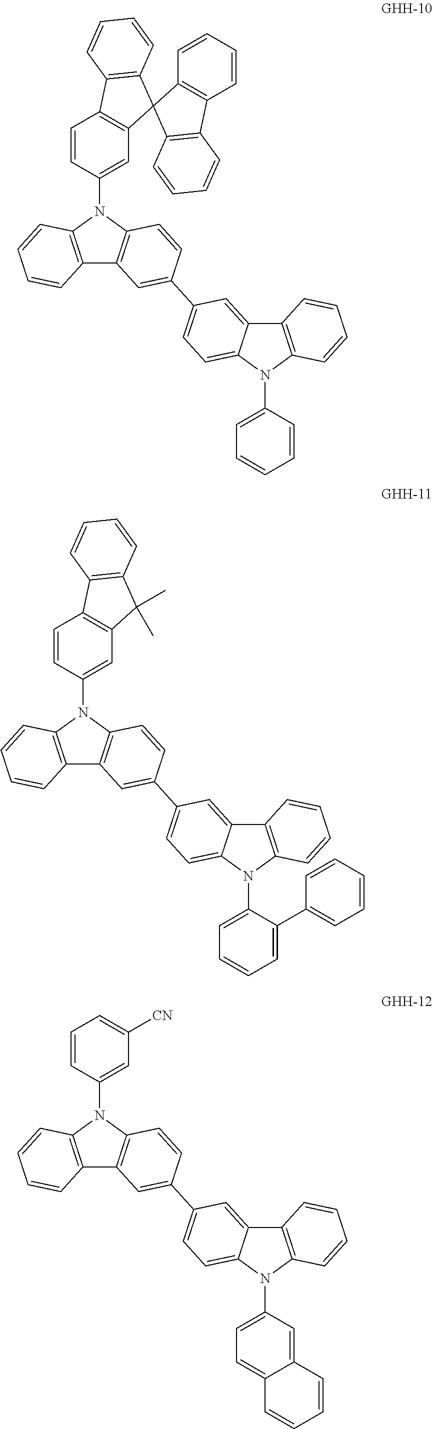 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

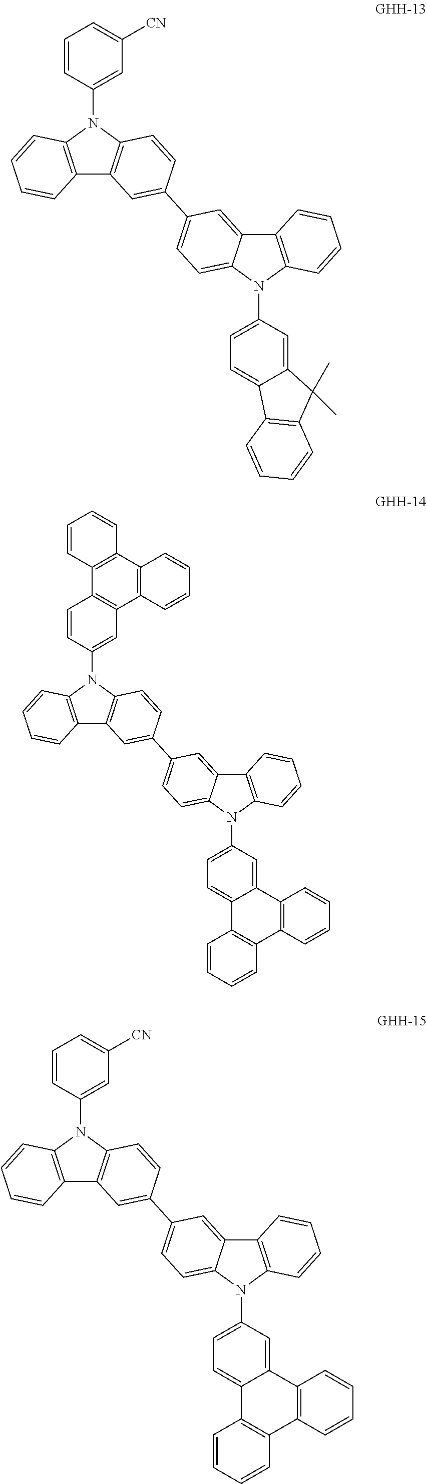 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

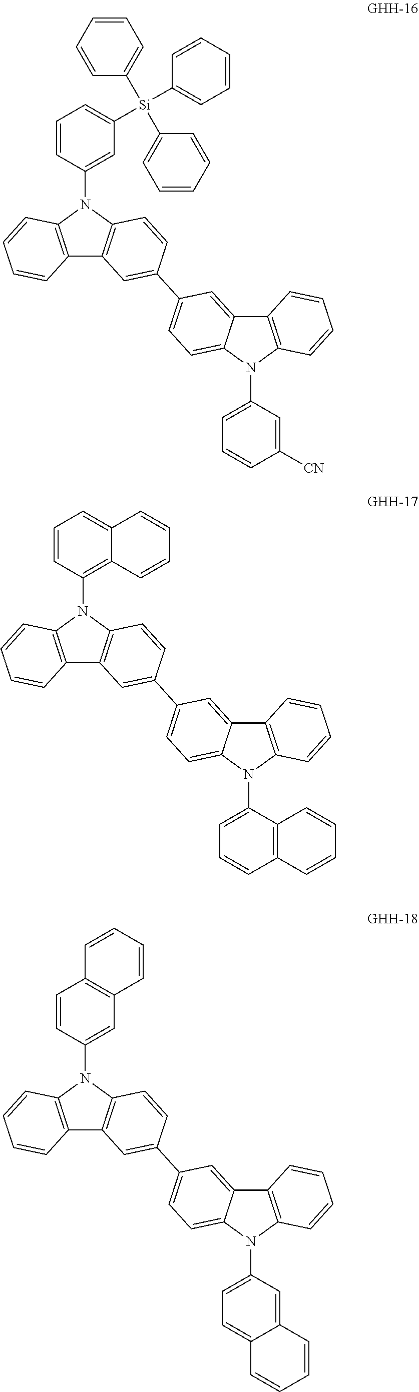 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

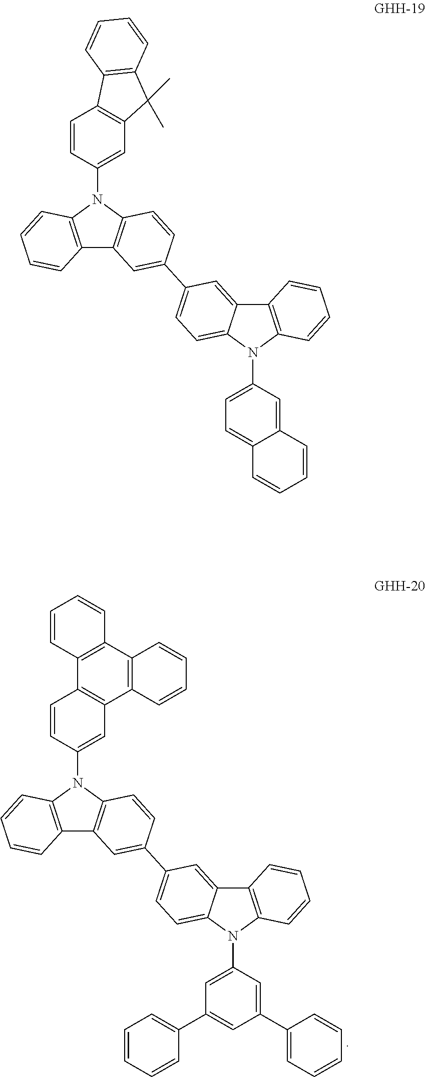 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1]

15. The organic light-emitting device of claim 12, wherein the compound represented by Chemical Formula 3 comprises one chosen from compound GEH-1 to compound GEH-20:

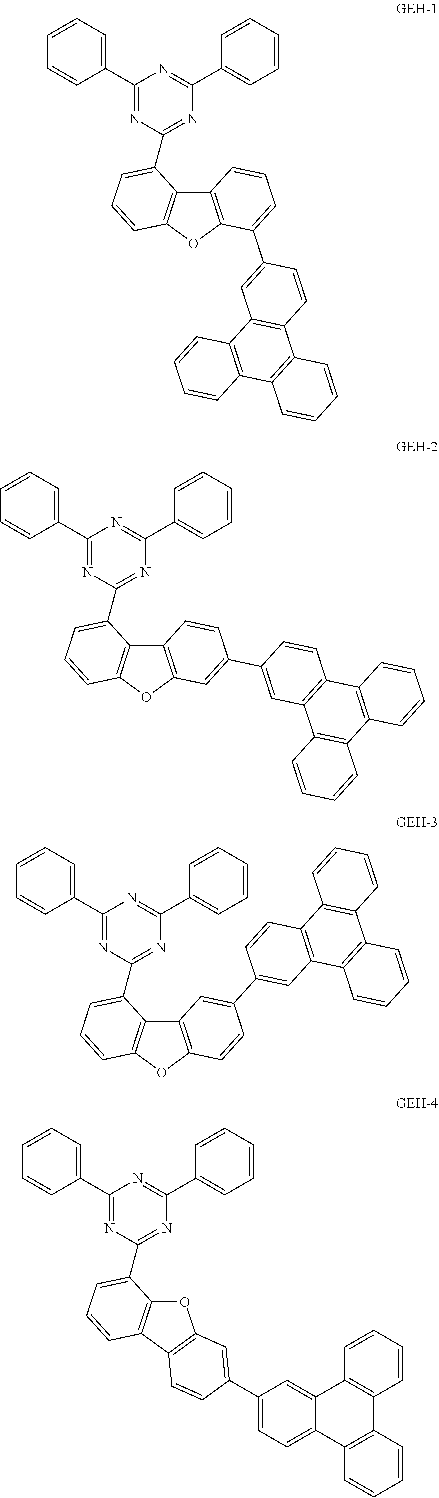 [SMILES: c1ccc(-c2nc(-c3ccccc3)nc(-c3cccc4oc5c(-c6ccc7c8ccccc8c8ccccc8c7c6)cccc5c34)n2)cc1 ; c1ccc(-c2nc(-c3ccccc3)nc(-c3cccc4oc5cc(-c6ccc7c8ccccc8c8ccccc8c7c6)ccc5c34)n2)cc1 ; c1ccc(-c2nc(-c3ccccc3)nc(-c3cccc4oc5ccc(-c6ccc7c8ccccc8c8ccccc8c7c6)cc5c34)n2)cc1 ; c1ccc(-c2nc(-c3ccccc3)nc(-c3cccc4c3oc3cc(-c5ccc6c7ccccc7c7ccccc7c6c5)ccc34)n2)cc1]

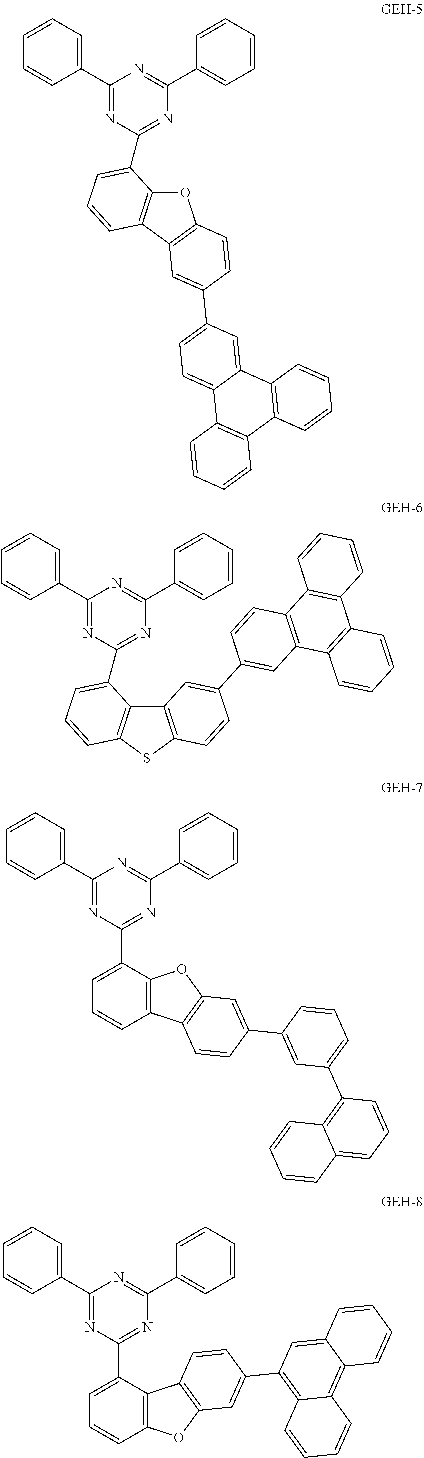 [SMILES: c1ccc(-c2nc(-c3ccccc3)nc(-c3cccc4c3oc3ccc(-c5ccc6c7ccccc7c7ccccc7c6c5)cc34)n2)cc1 ; c1ccc(-c2nc(-c3ccccc3)nc(-c3cccc4sc5ccc(-c6ccc7c8ccccc8c8ccccc8c7c6)cc5c34)n2)cc1 ; c1ccc(-c2nc(-c3ccccc3)nc(-c3cccc4c3oc3cc(-c5cccc(-c6cccc7ccccc67)c5)ccc34)n2)cc1 ; c1ccc(-c2nc(-c3ccccc3)nc(-c3cccc4oc5cc(-c6cc7ccccc7c7ccccc67)ccc5c34)n2)cc1]

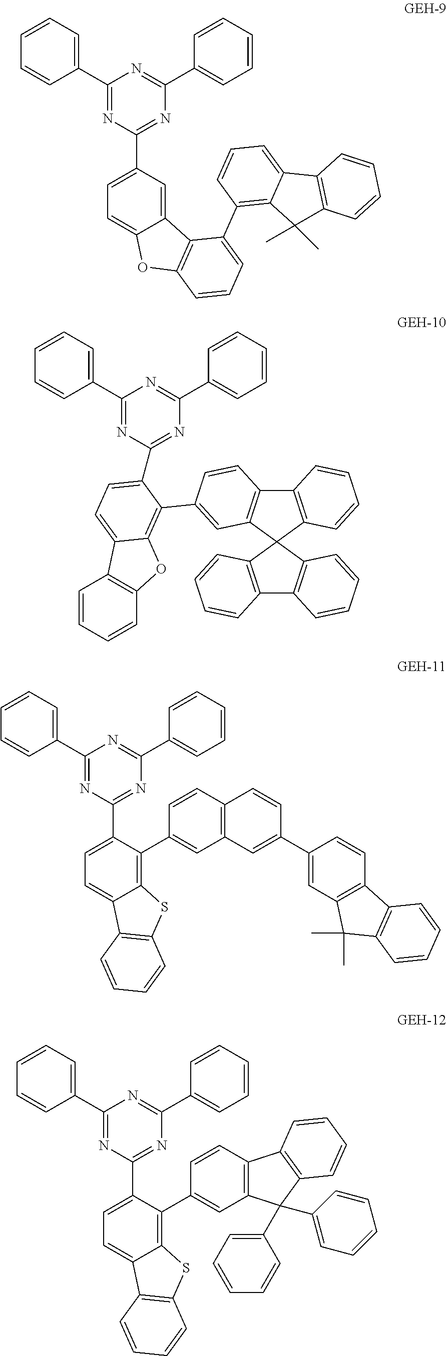

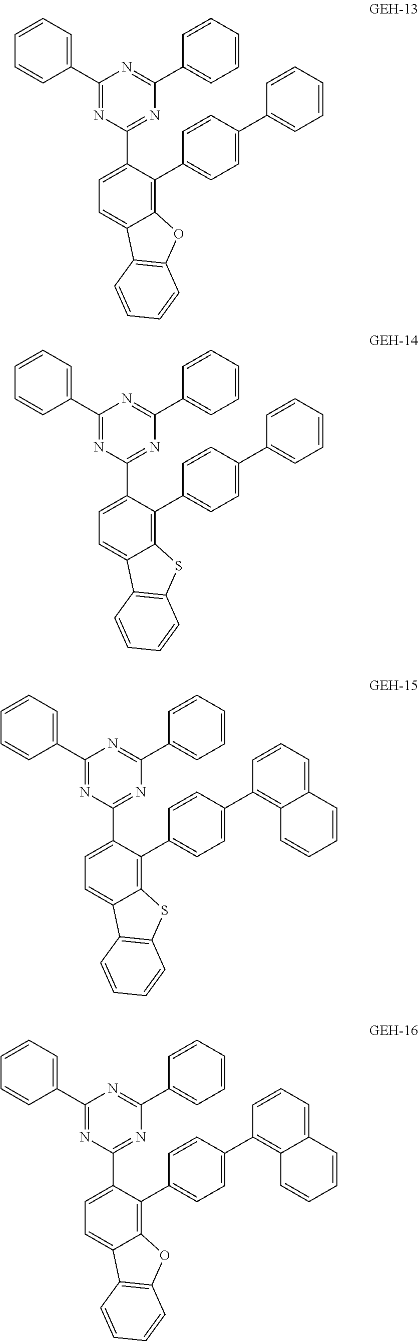 [SMILES: c1ccc(-c2ccc(-c3c(-c4nc(-c5ccccc5)nc(-c5ccccc5)n4)ccc4c3oc3ccccc34)cc2)cc1 ; c1ccc(-c2ccc(-c3c(-c4nc(-c5ccccc5)nc(-c5ccccc5)n4)ccc4c3sc3ccccc34)cc2)cc1 ; c1ccc(-c2nc(-c3ccccc3)nc(-c3ccc4c(sc5ccccc54)c3-c3ccc(-c4cccc5ccccc45)cc3)n2)cc1 ; c1ccc(-c2nc(-c3ccccc3)nc(-c3ccc4c(oc5ccccc54)c3-c3ccc(-c4cccc5ccccc45)cc3)n2)cc1]

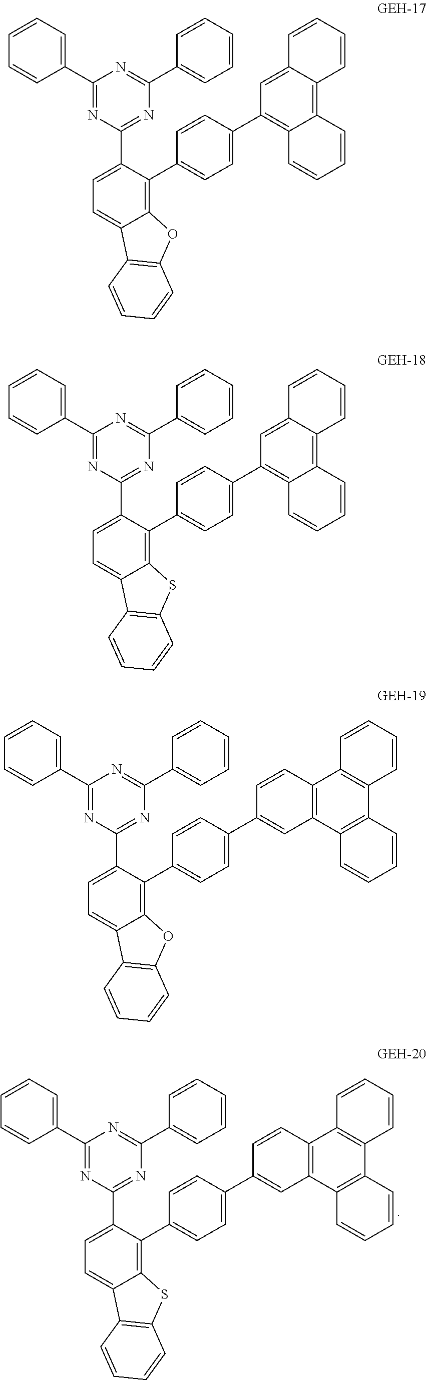 [SMILES: c1ccc(-c2nc(-c3ccccc3)nc(-c3ccc4c(oc5ccccc54)c3-c3ccc(-c4cc5ccccc5c5ccccc45)cc3)n2)cc1 ; c1ccc(-c2nc(-c3ccccc3)nc(-c3ccc4c(sc5ccccc54)c3-c3ccc(-c4cc5ccccc5c5ccccc45)cc3)n2)cc1 ; c1ccc(-c2nc(-c3ccccc3)nc(-c3ccc4c(oc5ccccc54)c3-c3ccc(-c4ccc5c6ccccc6c6ccccc6c5c4)cc3)n2)cc1 ; c1ccc(-c2nc(-c3ccccc3)nc(-c3ccc4c(sc5ccccc54)c3-c3ccc(-c4ccc5c6ccccc6c6ccccc6c5c4)cc3)n2)cc1]

16. An organic light-emitting device comprising:
a first electrode;
a second electrode facing the first electrode; and
a first light-emitting stack, a second light-emitting stack, and a third light-emitting stack disposed between the first electrode and the second electrode,
wherein each of the first light-emitting stack, the second light-emitting stack, and the third light-emitting stack includes at least one light-emissive layer,
wherein the at least one light-emissive layer comprises a green phosphorescent light-emissive layer,
wherein the green phosphorescent light-emissive layer includes a dopant material and a host material,
wherein the dopant material includes an organometallic compound represented by Chemical Formula 1,
wherein the host material includes a mixture of a compound represented by Chemical Formula 2 and a compound represented by Chemical Formula 3: 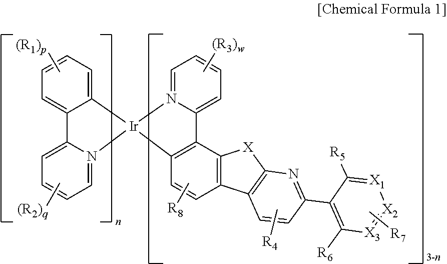
wherein in Chemical Formula 1,
X represents one chosen from oxygen (O), sulfur (S) and selenium (Se),
each of X₁, X₂ and X₃ independently represents nitrogen (N) or CR′,
each of R₁, R₂, R₃, R₄, R₇, R₈ and R′ independently represents one chosen from hydrogen, deuterium, halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₁, R₂, R₃, R₄, R₇, R₈ and R′ is unsubstituted or substituted with deuterium,
wherein each of R₅ and R₆ independently represents one chosen from halogen, halide, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, a isonitrile group, a sulfanyl group, a sulfinyl group, a sulfonyl group, a phosphino group, and combinations thereof, wherein at least one hydrogen of each of R₅ and R₆ is unsubstituted or substituted with deuterium,
n is an integer from 0 to 2,
p, q and w are independently an integer from 1 to 4, 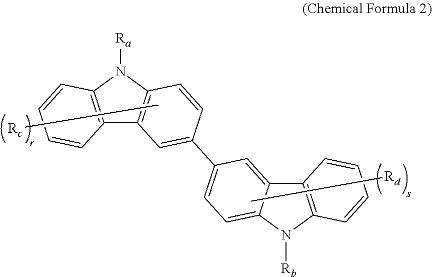
wherein in Chemical Formula 2,
each of Rₐ and R_{b} represents one chosen from a C3-C40 monocyclic aryl group, a polycyclic aryl group, a monocyclic heteroaryl group, and a polycyclic heteroaryl group, wherein each of Rₐ and R_{b} independently is unsubstituted or substituted with at least one substituent selected from a group consisting of an alkyl group, an aryl group, a heteroaryl group, a cyano group, an alkylsilyl group, and an arylsilyl group,
each of R_{c} and R_{d} represents one chosen from hydrogen, deuterium, halogen, a cyano group and an alkyl group, wherein each of r and s independently represents an integer from 0 to 7, wherein when r is 2 or more, each R_{c} in (R_{c})ᵣ is the same as or different from each other, wherein when s is 2 or more, each R_{d} in (R_{d})ₛ is the same as or different from each other, 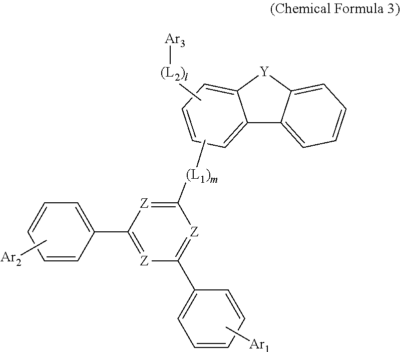
wherein in Chemical Formula 3,
each of Z_{S} independently represents nitrogen (N) or CR⁰, wherein at least two of Z_{S} are nitrogen (N),
R₀ represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Y represents either oxygen (O) or sulfur (S),
each of L₁ and L₂ independently represents one chosen from a single bond, hydrogen, deuterium, halogen, halide, an amino group, a nitrile group, a nitro group, an alkyl group, an alkenyl group, an alkynyl group, an alkoxy group, an aryloxy group and an arylene group,
each of l and m independently represents an integer from 0 to 2,
each of Ar₁ and Ar₂ independently represents one chosen from hydrogen, deuterium, halogen, halide, an amino group, a nitrile group, a nitro group, an alkyl group, an alkenyl group, an alkynyl group, an alkoxy group, an aryloxy group, an aryl group and a heteroaryl group,
Ar₃ represents a C6-C60 aryl group.

17. The organic light-emitting device of claim 16, wherein the organometallic compound represented by Chemical Formula 1 comprises one chosen from compound GD-1 to compound GD-10:

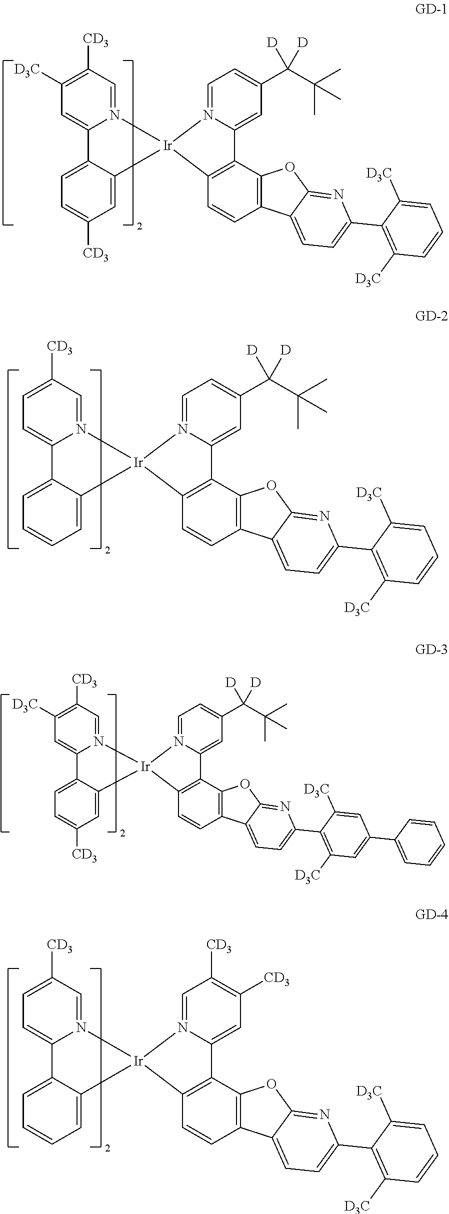

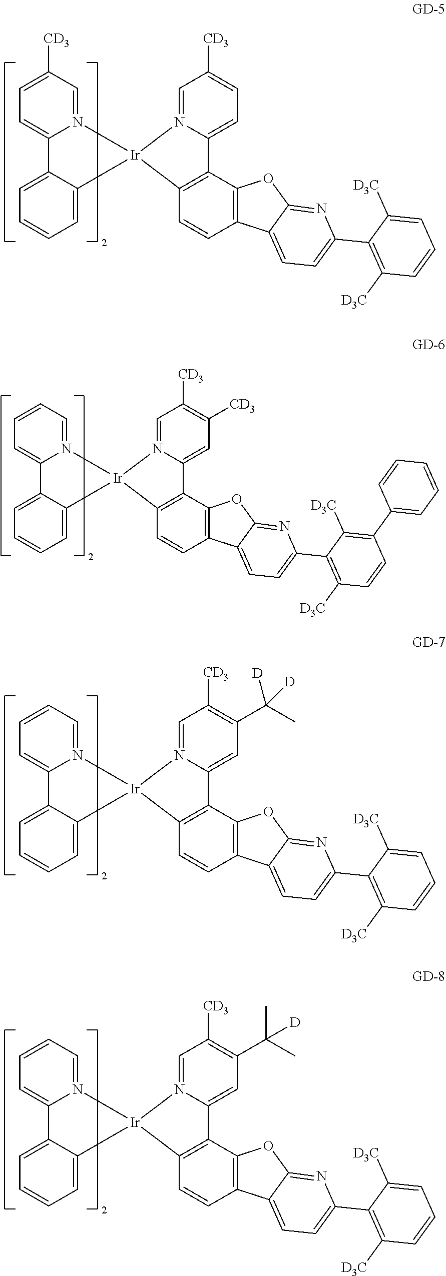

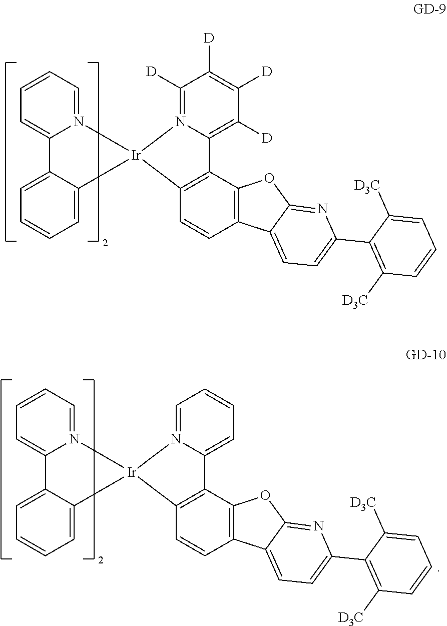

18. The organic light-emitting device of claim 16, wherein the compound represented by Chemical Formula 2 is one chosen from compound GHH-1 to compound GHH-20:

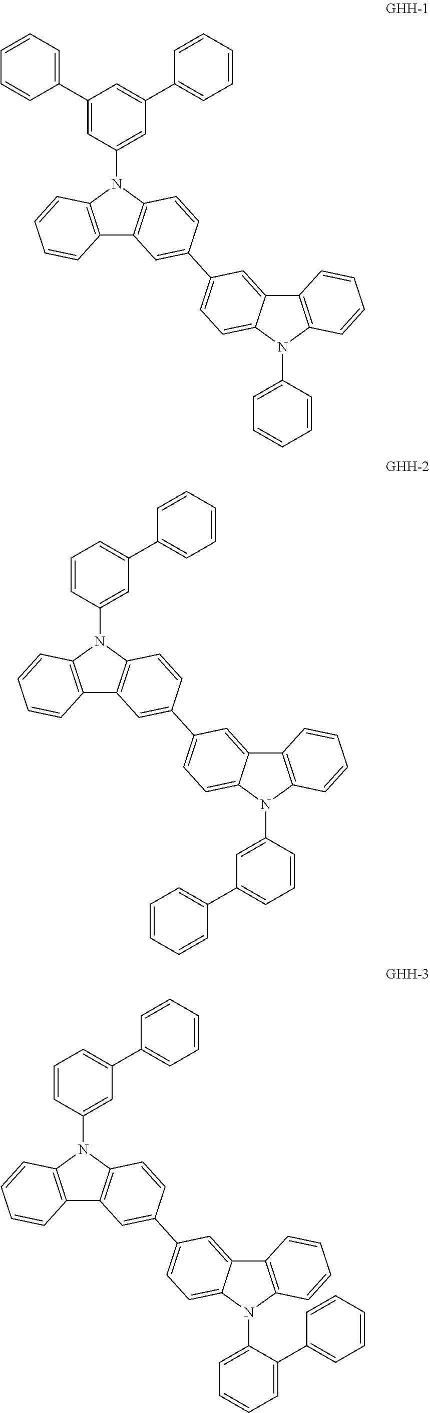

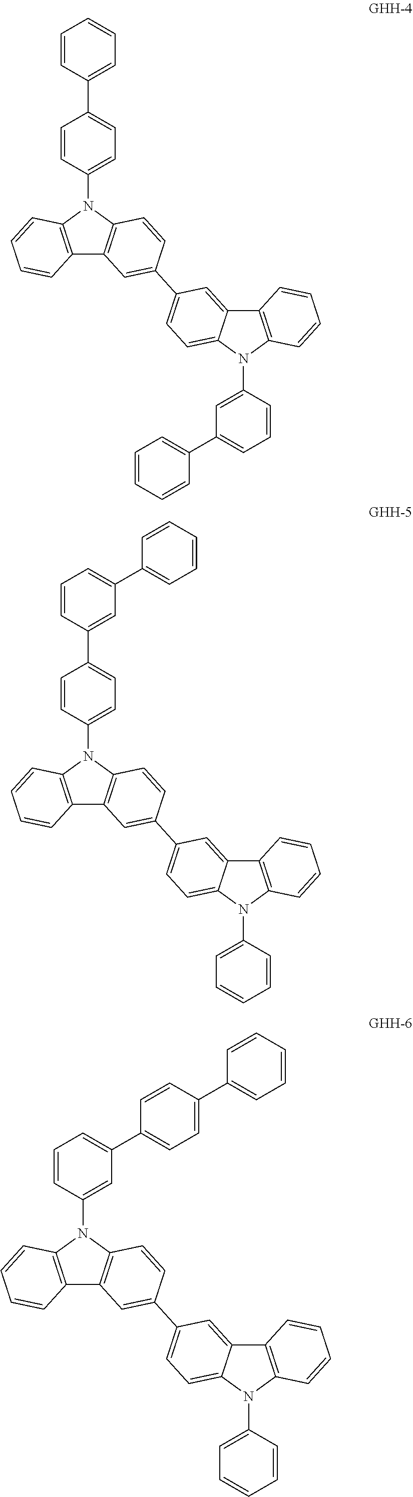

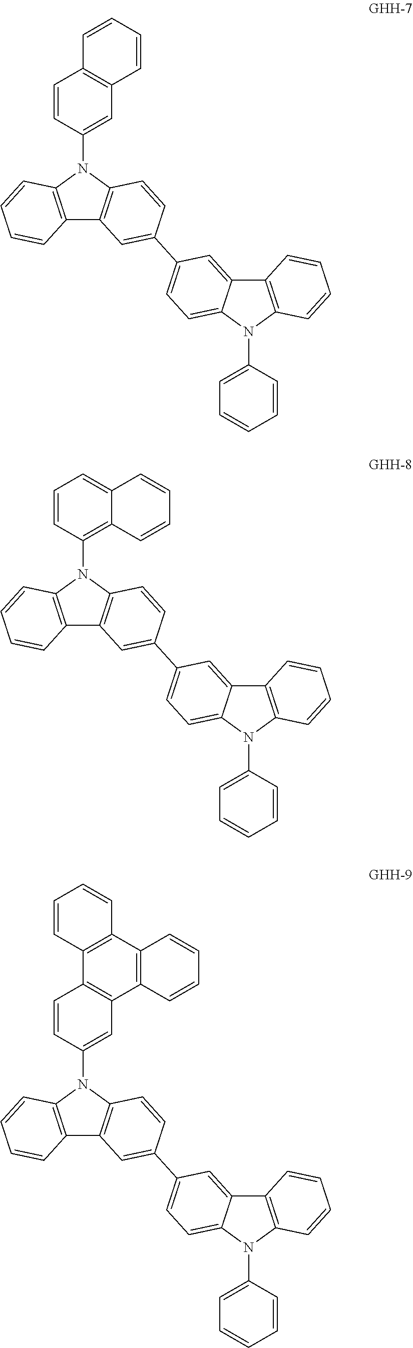 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

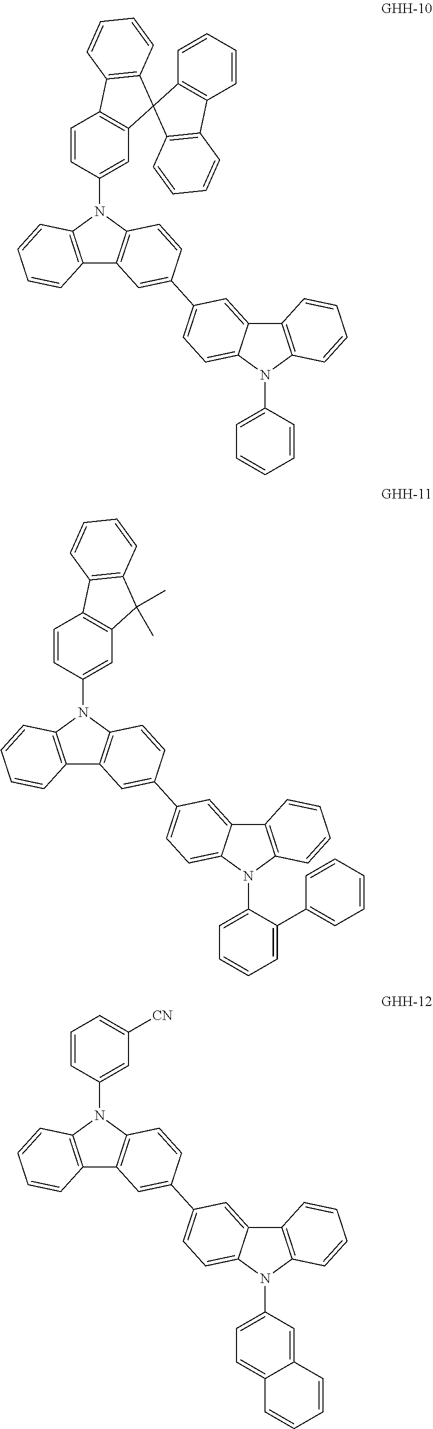 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

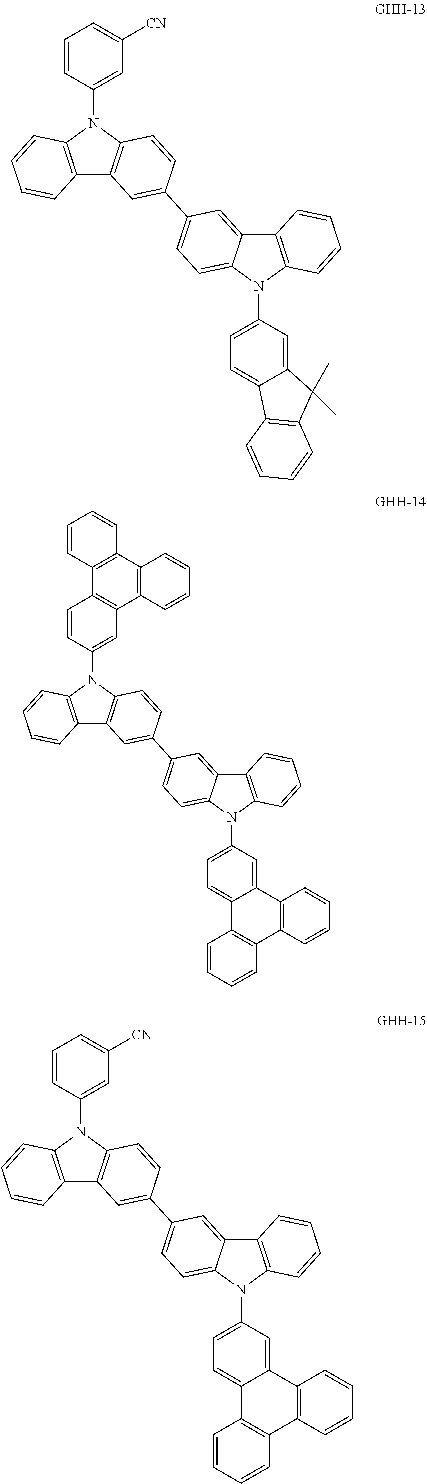 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

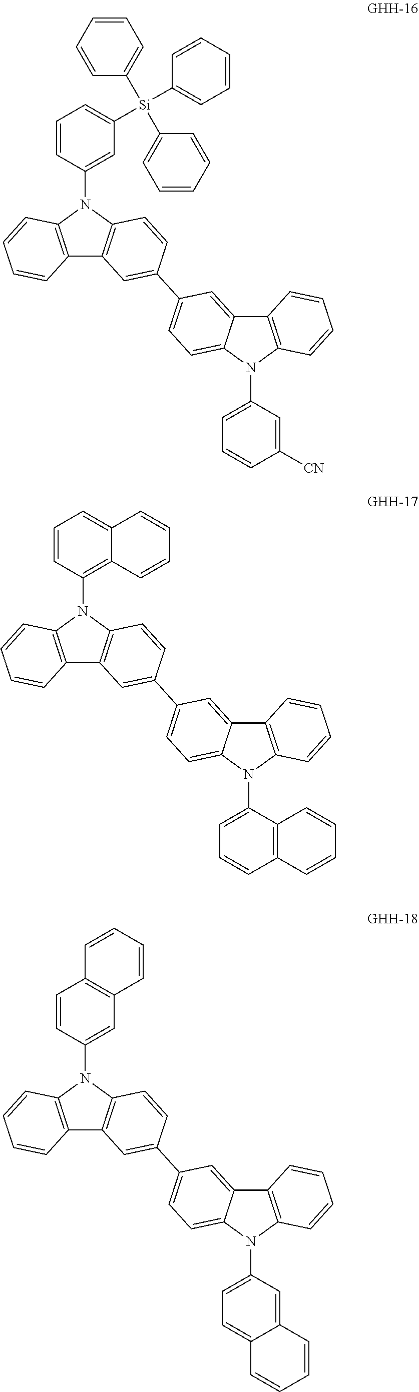 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

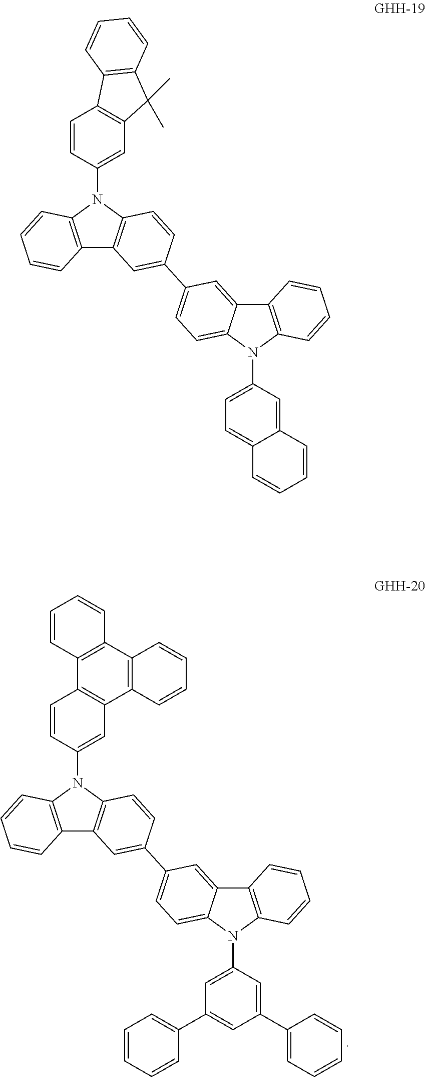 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1]

19. The organic light-emitting device of claim 16, wherein the compound represented by Chemical Formula 3 is one chosen from compound GEH-1 to compound GEH-20:

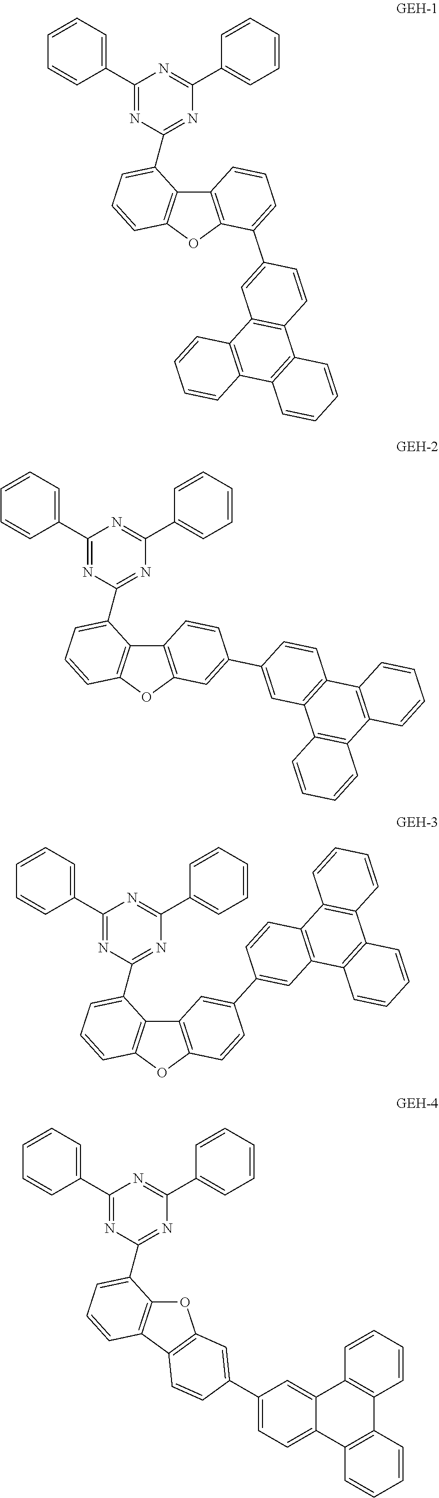 [SMILES: c1ccc(-c2nc(-c3ccccc3)nc(-c3cccc4oc5c(-c6ccc7c8ccccc8c8ccccc8c7c6)cccc5c34)n2)cc1 ; c1ccc(-c2nc(-c3ccccc3)nc(-c3cccc4oc5cc(-c6ccc7c8ccccc8c8ccccc8c7c6)ccc5c34)n2)cc1 ; c1ccc(-c2nc(-c3ccccc3)nc(-c3cccc4oc5ccc(-c6ccc7c8ccccc8c8ccccc8c7c6)cc5c34)n2)cc1 ; c1ccc(-c2nc(-c3ccccc3)nc(-c3cccc4c3oc3cc(-c5ccc6c7ccccc7c7ccccc7c6c5)ccc34)n2)cc1]

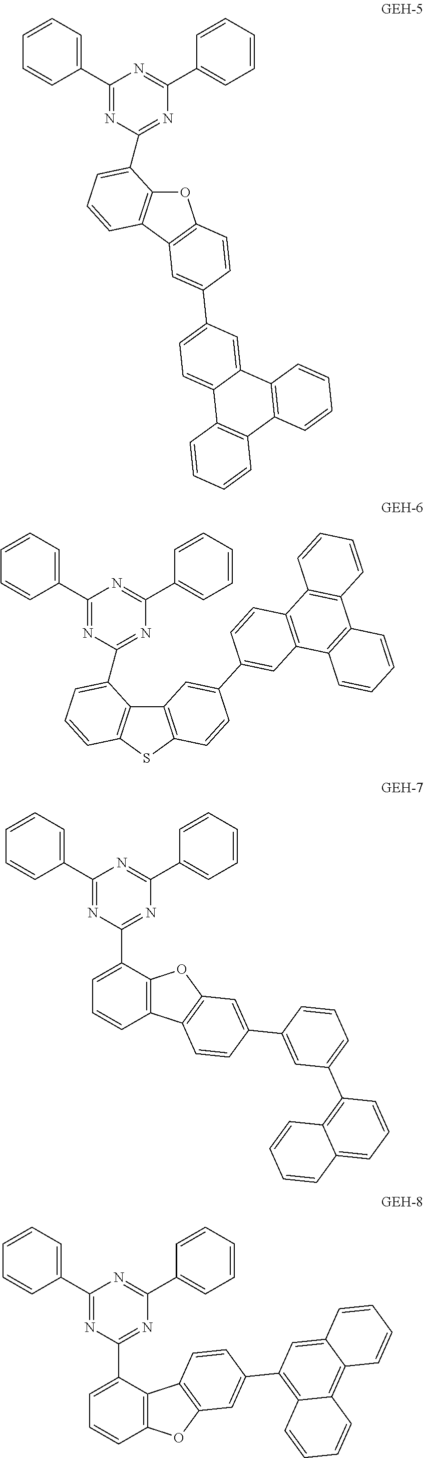 [SMILES: c1ccc(-c2nc(-c3ccccc3)nc(-c3cccc4c3oc3ccc(-c5ccc6c7ccccc7c7ccccc7c6c5)cc34)n2)cc1 ; c1ccc(-c2nc(-c3ccccc3)nc(-c3cccc4sc5ccc(-c6ccc7c8ccccc8c8ccccc8c7c6)cc5c34)n2)cc1 ; c1ccc(-c2nc(-c3ccccc3)nc(-c3cccc4c3oc3cc(-c5cccc(-c6cccc7ccccc67)c5)ccc34)n2)cc1 ; c1ccc(-c2nc(-c3ccccc3)nc(-c3cccc4oc5cc(-c6cc7ccccc7c7ccccc67)ccc5c34)n2)cc1]

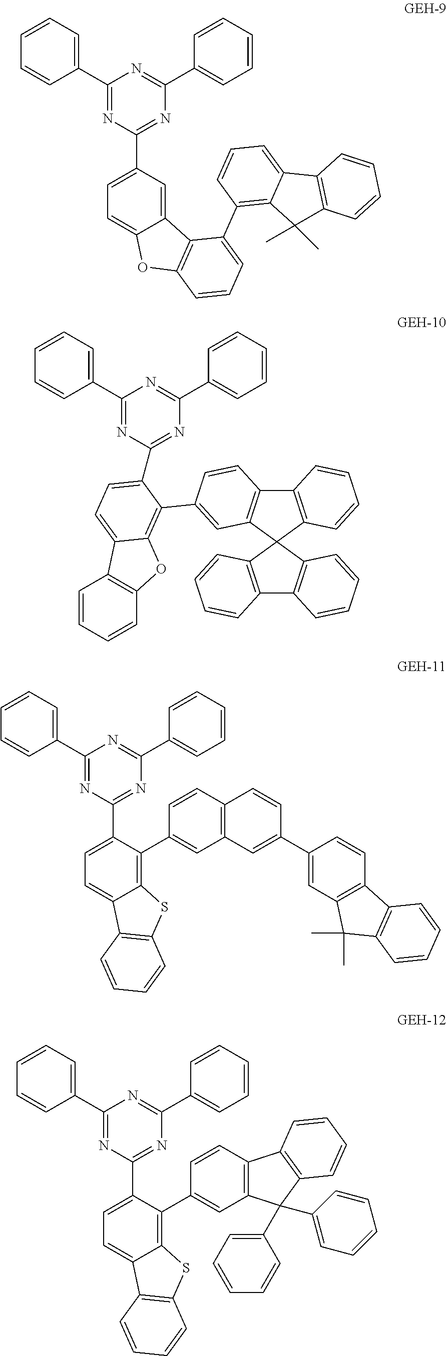

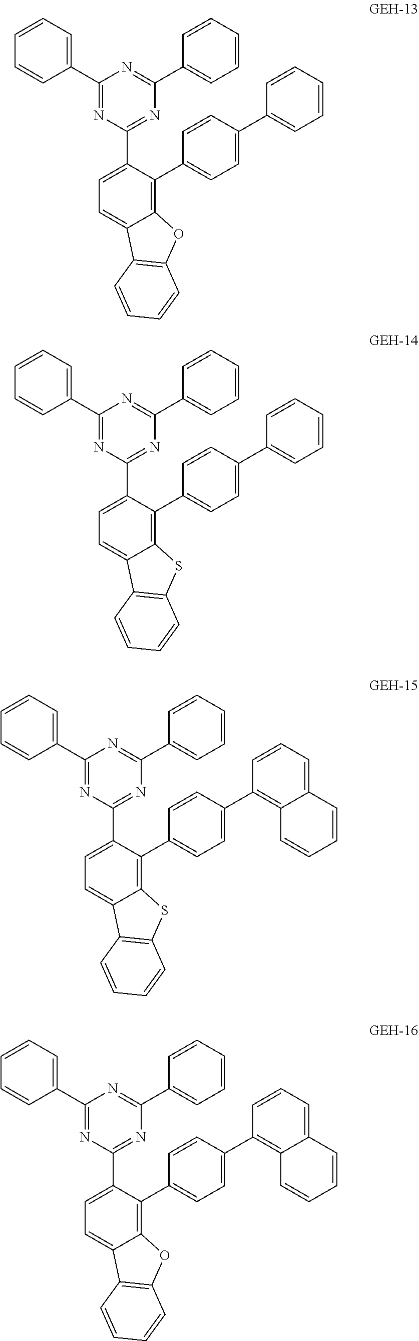 [SMILES: c1ccc(-c2ccc(-c3c(-c4nc(-c5ccccc5)nc(-c5ccccc5)n4)ccc4c3oc3ccccc34)cc2)cc1 ; c1ccc(-c2ccc(-c3c(-c4nc(-c5ccccc5)nc(-c5ccccc5)n4)ccc4c3sc3ccccc34)cc2)cc1 ; c1ccc(-c2nc(-c3ccccc3)nc(-c3ccc4c(sc5ccccc54)c3-c3ccc(-c4cccc5ccccc45)cc3)n2)cc1 ; c1ccc(-c2nc(-c3ccccc3)nc(-c3ccc4c(oc5ccccc54)c3-c3ccc(-c4cccc5ccccc45)cc3)n2)cc1]

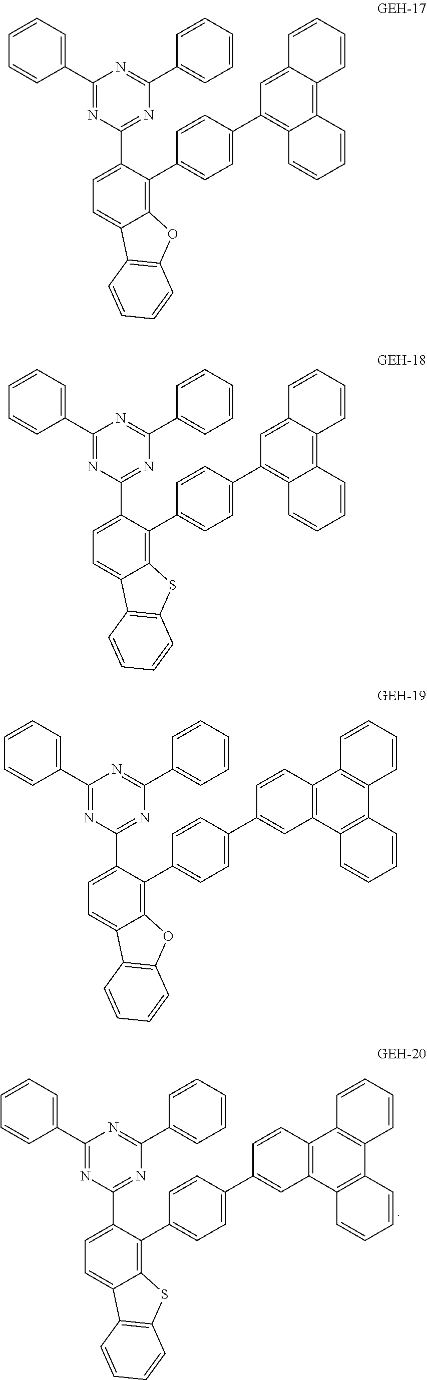 [SMILES: c1ccc(-c2nc(-c3ccccc3)nc(-c3ccc4c(oc5ccccc54)c3-c3ccc(-c4cc5ccccc5c5ccccc45)cc3)n2)cc1 ; c1ccc(-c2nc(-c3ccccc3)nc(-c3ccc4c(sc5ccccc54)c3-c3ccc(-c4cc5ccccc5c5ccccc45)cc3)n2)cc1 ; c1ccc(-c2nc(-c3ccccc3)nc(-c3ccc4c(oc5ccccc54)c3-c3ccc(-c4ccc5c6ccccc6c6ccccc6c5c4)cc3)n2)cc1 ; c1ccc(-c2nc(-c3ccccc3)nc(-c3ccc4c(sc5ccccc54)c3-c3ccc(-c4ccc5c6ccccc6c6ccccc6c5c4)cc3)n2)cc1]

20. An organic light-emitting display device comprising:
a substrate;
a driving element disposed on the substrate; and
an organic light-emitting diode disposed on the substrate and connected to the driving element, wherein the organic light-emitting diode includes the organic light-emitting device of claim 1.

21. An organic light-emitting display device comprising:
a substrate;
a driving element disposed on the substrate; and
an organic light-emitting diode disposed on the substrate and connected to the driving element, wherein the organic light-emitting diode includes the organic light-emitting device of claim 12.

22. An organic light-emitting display device comprising:
a substrate;
a driving element disposed on the substrate; and
an organic light-emitting diode disposed on the substrate and connected to the driving element, wherein the organic light-emitting diode includes the organic light-emitting device of claim 16.
